(19) United States
(12) Patent Application Publication
(10) Pub. No.: US 2011/0165518 A1
(43) Pub. Date: Jul. 7, 2011

(54) LITHOGRAPHIC PRINTING PLATE PRECURSOR

(75) Inventors: Paul Callant, Edegem (BE); Ineke Van Severen, Antwerpen (BE)

(73) Assignee: AGFA GRAPHICS NV, Mortsel (BE)

(21) Appl. No.: 13/062,747

(22) PCT Filed: Sep. 15, 2009
(86) PCT No.: PCT/EP09/61927

§ 371 Date: Mar. 8, 2011

Related U.S. Application Data
(60) Provisional application No. 61/098,808, filed on Sep. 22, 2008.

(30) Foreign Application Priority Data
Sep. 16, 2008 (EP) 08105354.8

(51) Int. Cl. G03F 7/004; G03F 7/20

(52) U.S. Cl. 430/281.1; 430/270.1; 430/302

(57) ABSTRACT

A lithographic printing plate precursor includes a coating provided on a support having a hydrophilic surface, the coating containing thermoplastic polymer particles and an infrared radiation absorbing dye characterized in that the dye contains a substituent selected from bromo and iodo.

### BACKGROUND OF THE INVENTION

1. Field of the Invention

The present invention relates to a heat-sensitive, negative-working lithographic printing plate precursor.

2. Description of the Related Art

Lithographic printing presses use a so-called printing master such as a printing plate which is mounted on a cylinder of the printing press. The master carries a lithographic image on its surface and a print is obtained by applying ink to the image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called driographic printing, the lithographic image consists of ink-accepting and ink-adhesive (ink-repelling) areas and during driographic printing, only ink is supplied to the master.

Printing masters are generally obtained by the image-wise exposure and processing of an imaging material called plate precursor. In addition to the well-known photosensitive, so-called pre-sensitized plates, which are suitable for UV contact exposure through a film mask, also heat-sensitive printing plate precursors have become very popular in the late 1990s. Such thermal materials offer the advantage of daylight stability and are especially used in the so-called computer-to-plate method wherein the plate precursor is directly exposed, i.e. without the use of a film mask. The material is exposed to heat or to infrared radiation and the generated heat triggers a (physico-)chemical process, such as ablation, polymerization, insolubilization by cross linking of a polymer, heat-induced solubilization, or particle coagulation of a thermoplastic polymer latex.

The most popular thermal plates form an image by a heat-induced solubility difference in an alkaline developer between exposed and non-exposed areas of the coating. The coating typically comprises an oleophilic binder, e.g. a phenolic resin, of which the rate of dissolution in the developer is either reduced (negative working) or increased (positive working), by the image-wise exposure. During processing, the solubility differential leads to the removal of the non-image (non-printing) areas of the coating, thereby revealing the hydrophilic support, while the image (printing) areas of the coating remain on the support. Typical examples of such plates are described in e.g. EP-As 625 728, 823 327, 825 927, 864 420, 894 622 and 901 902. Negative working embodiments of such thermal materials often require a pre-heat step between exposure and development as described in e.g. EP-A 625 728.

Negative working plate precursors which do not require a pre-heat step may contain an image-recording layer that works by heat-induced particle coalescence of a thermoplastic polymer latex, as described in e.g. EP-As 770 494, 770 495, 770 496 and 770 497. These patents disclose a method for making a lithographic printing plate comprising the steps of (1) image-wise exposing an imaging element comprising hydrophobic thermoplastic polymer particles dispersed in a hydrophilic binder and a compound capable of converting light into heat and (2) developing the image-wise exposed element by applying fountain and/or ink.

EP-A 1 342 568 describes a method of making a lithographic printing plate comprising the steps of (1) image-wise exposing an imaging element comprising hydrophobic thermoplastic polymer particles dispersed in a hydrophilic binder and a compound capable of converting light into heat and (2) developing the image-wise exposed element by applying a gum solution, thereby removing non-exposed areas of the coating from the support.

WO 2006/037716 describes a method for preparing a lithographic printing plate which comprises the steps of (1) image-wise exposing an imaging element comprising hydrophobic thermoplastic polymer particles dispersed in a hydrophilic binder and a compound capable of converting light into heat and (2) developing the image-wise exposed element by applying a gum solution, thereby removing non-exposed areas of the coating from the support and characterised by an average particle size of the thermoplastic polymer particles between 40 nm and 63 nm and wherein the amount of the hydrophobic thermoplastic polymer particles is more than 70% and less than 85% by weight, relative to the image recording layer.

EP-A 1 614 538 describes a negative working lithographic printing plate precursor which comprises a support having a hydrophilic surface or which is provided with a hydrophilic layer and a coating provided thereon, the coating comprising an image-recording layer which comprises hydrophobic thermoplastic polymer particles and a hydrophilic binder, characterised in that the hydrophobic thermoplastic polymer particles have an average particle size in the range from 45 nm to 63 nm, and that the amount of the hydrophobic thermoplastic polymer particles in the image-recording layer is at least 70% by weight relative to the image-recording layer.

EP-A 1 614 539 and EP-A 1 614 540 describes a method of making a lithographic printing plate comprising the steps of (1) image-wise exposing an imaging element as disclosed in EP-A 1 614 538 and (2) developing the image-wise exposed element by applying an aqueous, alkaline solution.

EP-A 1 736 312 and EP 1 910 082 disclose lithographic printing plate precursors comprising an IR-dye which is capable of forming a print out image upon exposure to IR radiation. The visible print out image is formed by a chemical transformation of the IR-dye upon exposure to IR radiation. Precursors capable of forming a print out image upon IR exposure are very well suited to be used in an on-press processing set-up, wherein the exposed precursor is mounted on the press and the non-image areas are subsequently removed by applying ink and/or fountain to the mounted precursor. The formation of a print out image enables a visible inspection of the non-processed precursor before mounting it on the press.

EP-As 1 859 935 and EP 1 859 936 disclose a lithographic printing plate precursor comprising thermoplastic particles having an average particle size between 10 and 40 wm and wherein the amount of IR-dye is adjusted as function of the particle size of the polymer particles. EP 1 914 068 and EP 1 914 069 disclose a lithographic printing plate precursor comprising thermoplastic particles wherein, in addition to an IR-dye, a dye, respectively absorbing in the UV and the visible region of the spectrum, is present.

EP-A 1 223 196 discloses an IR sensitive photopolymer plate precursor comprising an IR cyanine dye containing an atom having an atomic weight of at least 28, such as a halogen atom, or a substituent that contains a non-covalent electron pair such as a carbonyl group. EP-A 1 464 486 discloses an IR sensitive photopolymer plate precursor comprising an IR cyanine dye having an electron-withdrawing group or a heavy atom-containing group on the hetercylic side groups of the dye.

There is a continuous need to further improve the properties of lithographic printing plate precursors with which printing plates are produced based on coalescence of thermoplastic particles upon exposure to IR radiation. Especially an increase of the sensitivity, enabling a higher throughput, i.e. number of printing plates that can be produced in a given time interval, without adversely affecting the other lithographic properties, for example the clean-out behaviour, would render this type of printing plate precursors even more competitive against precursors using a different technology, for example heat induced photopolymerization or solubilization.

### SUMMARY OF THE INVENTION

Preferred embodiments of the present invention provide a lithographic printing plate precursor comprising thermoplastic particles and an IR-dye with an increased sensitivity and/or an improved clean-out behaviour.

Another preferred embodiment of the present invention provides a method of preparing printing plates wherein the throughput is increased while the lithographic properties of the obtained printing plates are not adversely affected.

The first preferred embodiment of the present invention is realized by the lithographic printing plate precursor as defined below. Other preferred embodiments of the precursor are also defined below.

The second preferred embodiment of the present invention is realized by the method of preparing lithographic printing plates as defined below.

### DETAILED DESCRIPTION OF PREFERRED EMBODIMENTS

The printing plate precursor comprises a coating provided on a support having a hydrophilic surface. The coating may comprise one or more layer(s). The layer of the coating comprising thermoplastic particles is referred to as the image-recording layer.

### IR Radiation Absorbing Dye

The lithographic printing plate precursor comprises a dye which absorbs infrared (IR) radiation and converts the absorbed energy into heat. Preferred IR absorbing dyes (IR-dyes) are cyanine dyes. Other IR-dyes which may be used are merocyanine, indoaniline, oxonol, pyrylium and squarylium dyes.

The IR-dyes according to a preferred embodiment of the present invention contain a substituent selected from bromo and iodo. Preferably, the IR-dyes contain two substituents selected from bromo and iodo. However the IR-dye may contain three, four or more substituents selected from bromo and iodo.

Preferably, the IR-dye is a cyanine dye having a structure according to Formula I

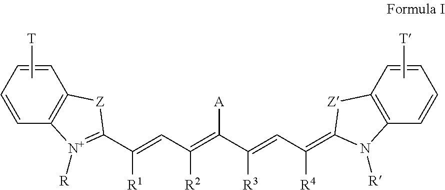

wherein

Z and Z′ represent —S—, —CR^{a}R^{b}— or —CH═CH—;

R^{a} and R^{b} represent an alkyl, aralkyl or aryl group;

A represents hydrogen, an optionally substitued alkyl, aralkyl or aryl group, halogen, —OR^{c}, —SR^{d}, —SO₂R^{e}, —NR^{f}R^{g}, —NR^{h}(SO₂Rⁱ) or —NR^{j}(CO₂R^{k}) wherein
R^{c} represents an optionally substituted aryl group,
R^{d} represents an optionally substituted alkyl, aralkyl, aryl or heteroaryl group,
R^{e} represents an optionally substituted alkyl, aryl, or heteroaryl group,
R^{f} represents an optionally substituted alkyl, aralkyl or aryl group,
R^{g} represents an optionally substituted aryl group,
R^{h} represents an optionally substituted alkyl or aryl group,
Rⁱ represents an optionally substituted alkyl or aryl group or —NRⁱ¹Rⁱ² wherein Rⁱ¹ and Rⁱ² represent hydrogen, an optionally substituted alkyl or aryl group,
R^{j} represents an optionally substituted alkyl or aryl group;
R^{k}, R and R′ represent an optionally substituted alkyl group;

R¹, R², R³ and R⁴ represent hydrogen or an optionally substituted alkyl group;

R, R′ and R¹ to R⁴ may form a ring;

T and T′ independently represent hydrogen, halogen, alkyl, alkoxy, cyano, —CO₂R^{k}, —CONR^{l}R^{m}, —SO₂Rⁿ, —SO₂NR^{o}R^{p} or an optionally substituted annulated benzo ring wherein

R^{l}, R^{m} represent hydrogen, an optionally substituted alkyl or aryl group,

Rⁿ represents an optionally substituted alkyl or aryl group and

R^{o} and R^{p} represent hydrogen, an optionally

substituted alkyl or aryl group.

The cyanine dyes according to Formula I contain a substituent, preferably two substituents, selected from bromo and iodo. Particularly preferred, the bromo and/or iodo substituents are located on the heterocyclic end groups and/or on the meso-substituent A.

The cyanine dyes according to Formula I are preferably anionic, i.e. negatively charged, especially when used in combination with anionic stabilized thermoplastic polymer particles. The cyanine dyes are preferably rendered anionic by introducing optionally substituted sulpho-alkyl groups on the heterocyclic side groups of the cyanine dyes.

Particularly preferred, the cyanine dyes have a structure according to Formulae II to V. The cyanine dyes according to Formulae II to V contain a substituent, preferably two substituents, selected from bromo and iodo. Particularly preferred, the bromo and/or iodo substituents are located on the heterocyclic end groups and/or on the meso-substituent A.

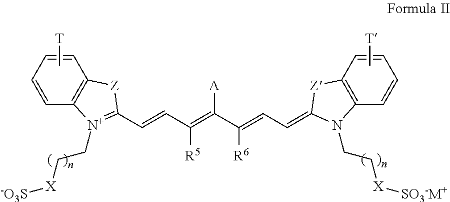

wherein

T, T, Z, Z′ and A have the same meaning as in Formula I;

R⁵ and R⁶ represent the necessary atoms to form a ring;

n represents an integer ranging from 0 to 3;

X represents —CH₂—, —O— or —S—;

M⁺ represents a counterion to balance the charge.

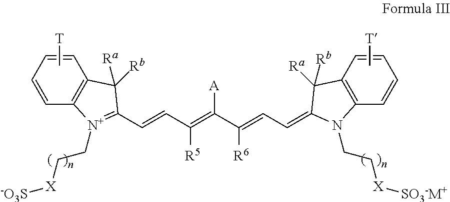

wherein

T, T′, R^{a}, R^{b} and A have the same meaning as in Formula I;

R⁵ and R⁶ represent the necessary atoms to form a ring;

n represents an integer ranging from 0 to 3;

X represents —CH₂—, —O— or —S—;

M⁺ represents a counterion to balance the charge.

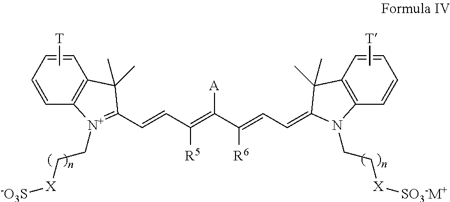

wherein

T, T′ and A have the same meaning as in Formula I;

R⁵ and R⁶ represent the necessary atoms to form a ring;

n represents an integer ranging from 0 to 3;

X represents —CH₂—, —O— or —S—;

M⁺ represents a counterion to balance the charge.

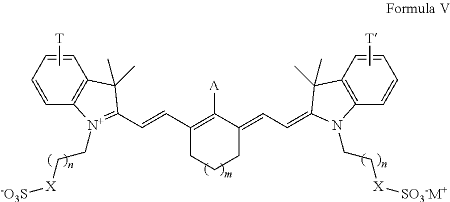

wherein

T, T′ and A have the same meaning as in Formula I;

n represents an integer ranging from 0 to 3;

m represents 0 or 1;

X represents —CH₂—, —O— or —S—;

M⁺ represents a counterion to balance the charge.

According to a highly preferred embodiment, the cyanine dyes have a structure according to Formulae VI to VIII. The cyanine dyes according to Formulae VI to VIII contain a substituent, preferably two substituents, selected from bromo and iodo. Particularly preferred, the bromo and/or iodo substituents are located on the heterocyclic end groups and/or on the meso-substituent A.

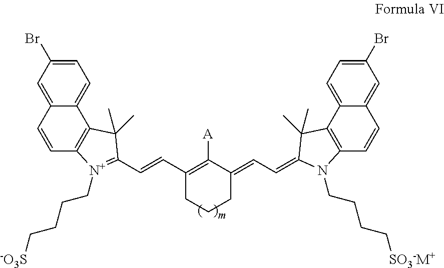

wherein

A has the same meaning as in Formula I;

m represents 0 or 1;

M⁺ represents a counterion to balance the charge.

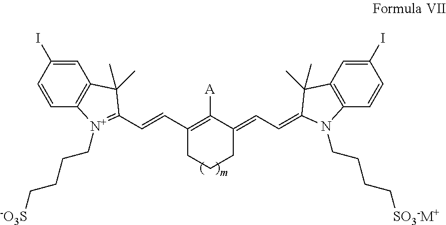

wherein

A has the same meaning as in Formula I;

m represents 0 or 1;

M⁺ represents a counterion to balance the charge.

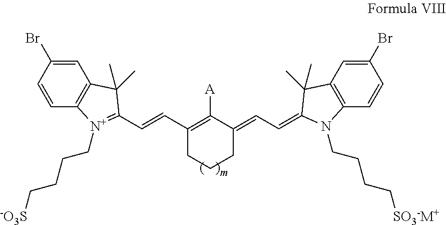

wherein
A has the same meaning as in Formula I;
m represents 0 or 1;
M⁺ represents a counterion to balance the charge.

Lithographic printing plate precursors according to preferred embodiment of the present invention are characterized by a higher sensitivity and/or an improved clean-out behaviour.

It has been observed that precursors comprising IR-dyes capable of forming a print out image upon IR exposure and containing a substituent, preferably two substituents, selected from bromo and iodo are capable of forming the print out image at a lower energy density, compared to precursors comprising IR-dyes without such substituents. IR-dyes according to a preferred embodiment of the present invention capable of forming a print out image are cyanine dyes according to Formulae II to VIII wherein A represents —NR^{h}(SO₂Rⁱ) or —NR^{j}(CO₂R^{k}) and wherein R^{h}, Rⁱ, R^{j} and R^{k} have the same meaning as in Formula I. Preferred IR-dyes capable of forming a print out image are cyanine dyes according to Formulae VI, VII and VIII wherein A represents —NR^{h}(SO₂Rⁱ) or —NR^{j}(CO₂R^{k}) and wherein R^{h}, Rⁱ, R^{j} and R^{k} have the same meaning as in Formula I. Using precursors comprising such IR-dyes enables the formation of a visible print out image even if the precursors are developed on-press.

It has also been observed that when using IR-dyes according to preferred embodiments of the present invention, especially the cyanine dyes according to Formulae II to VIII wherein A is a hydrophobic group, the observed improvements are even more pronounced. It may be that the presence of a hydrophobic group at the meso position of the cyanine dyes influences the adsorption behaviour of the IR-dye on the thermoplastic particles. The adsorption behaviour of the IR-dyes on the thermoplastic particles may influence the sensitivity of the precursor by an improved heat transfer to the particles and may influence the clean-out behaviour by better stabilizing the particles in an aqueous environment. Particularly good results are obtained when A is selected from

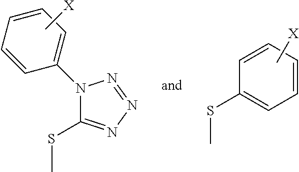

wherein X is an optional substituent, for example Br or I.

The IR-dye amount is preferably at least 6% by weight, more preferably at least 8% by weight, relative to the total weight of the ingredients of the image recording layer. As described in EP-A 1 859 936 the amount of IR-dye may be adjusted to the particle size of the thermoplastic particles. A single IR-dye or a mixture of two or more different IR-dyes according to a preferred embodiment of the present invention may be used. A mixture of one or more IR-dyes according to a preferred embodiment of the present invention and one or more other IR-dyes may also be used. A mixture of IR-dyes may be used to optimize the absorption of IR radiation by the heat sensitive lithographic printing plate precursor, for example in view of the IR laser used to expose the precursors.

The IR-dyes according to a preferred embodiment of the present invention may be added to the coating solution as an aqueous solution or as an aqueous dispersion. If the IR-dyes are not sufficiently soluble in water, it is preferred to add the IR-dyes to the coating solution as an aqueous dispersion. Using an aqueous dispersion of the IR-dye instead of, for example a solution of the IR-dye in a mixture of water and alcohol, reduces solvent emission during the manufacture of the precursors.

The preparation of cyanine dyes is well known in the art. These preparation methods as disclosed in for example WO 2002/24815, EP-A 1 736 312, WO 2006/136543, WO 2004/052995 and EP 738 707 may be used to prepare the IR-dyes according to a preferred embodiment of the present invention. A particularly preferred preparation method of cyanine dyes is disclosed in the unpublished EP-A 07 123 764.8 (filed on 2007 Dec. 20).

Examples of IR-dyes according to a preferred embodiment of the present invention are given below.

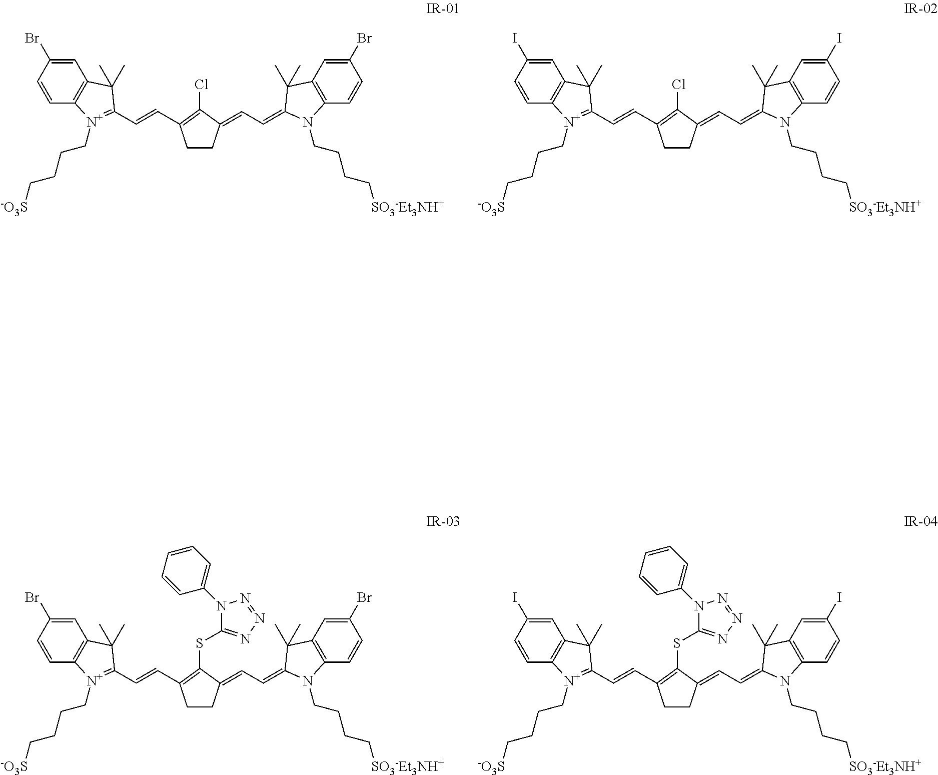

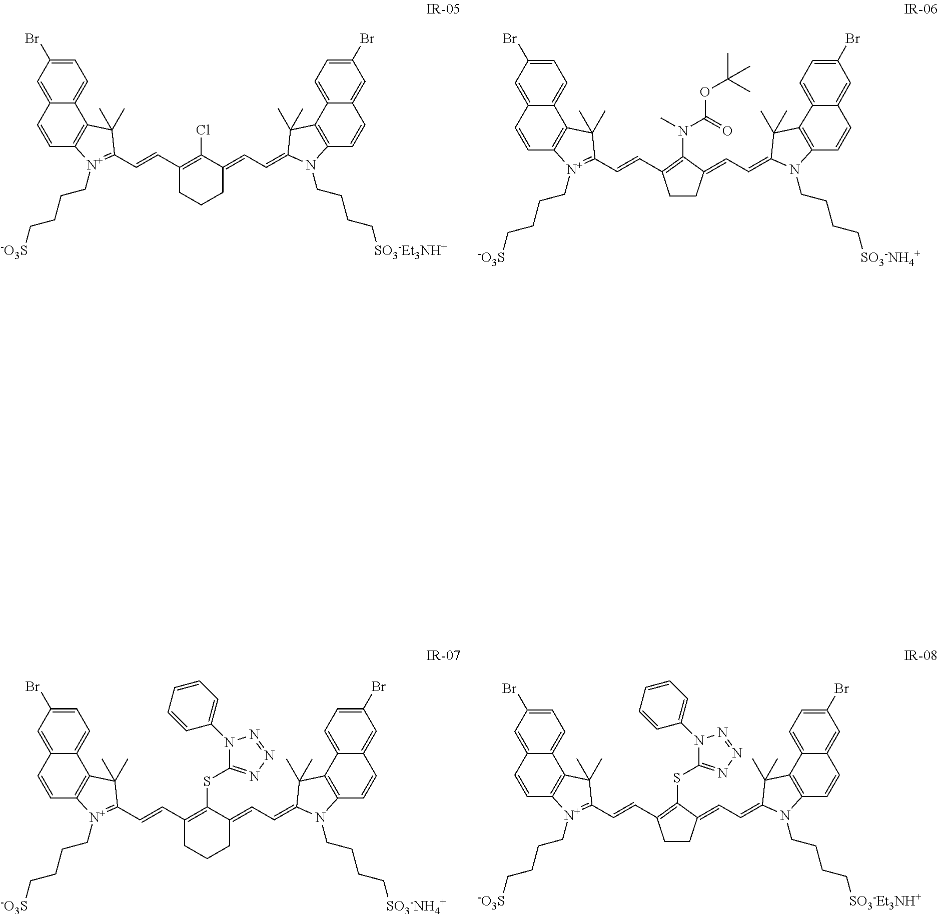

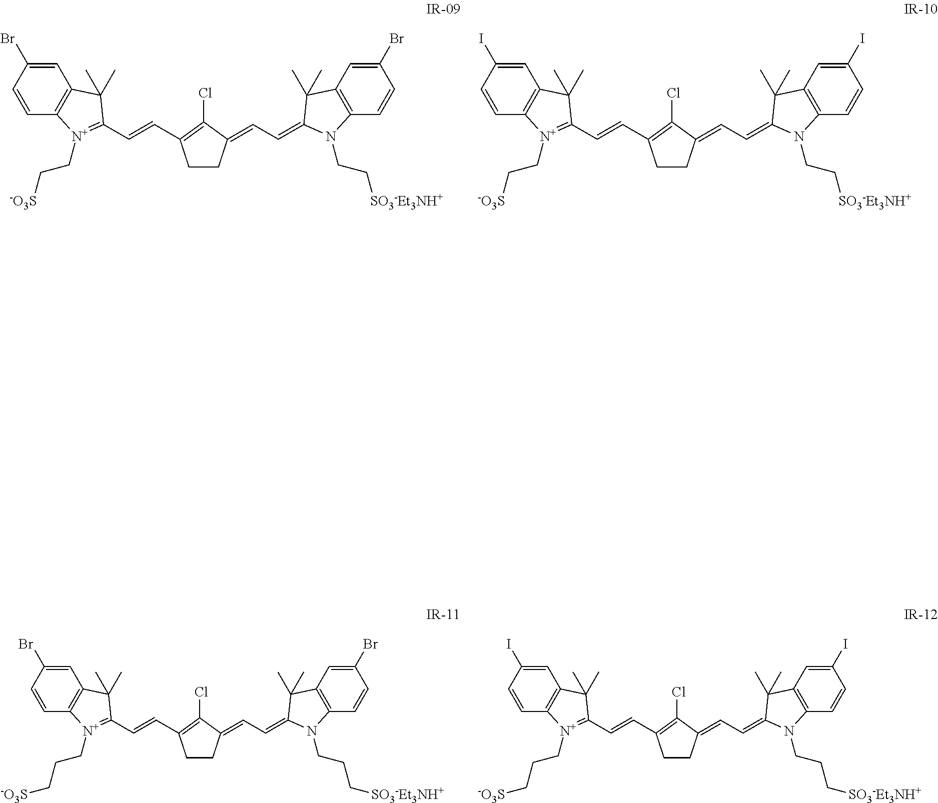

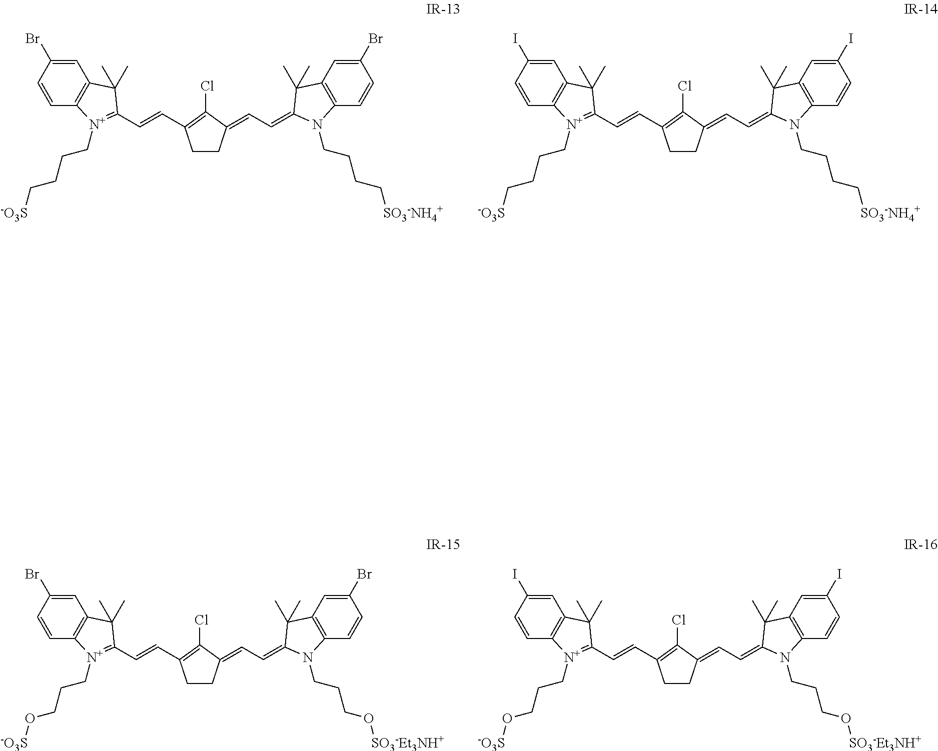

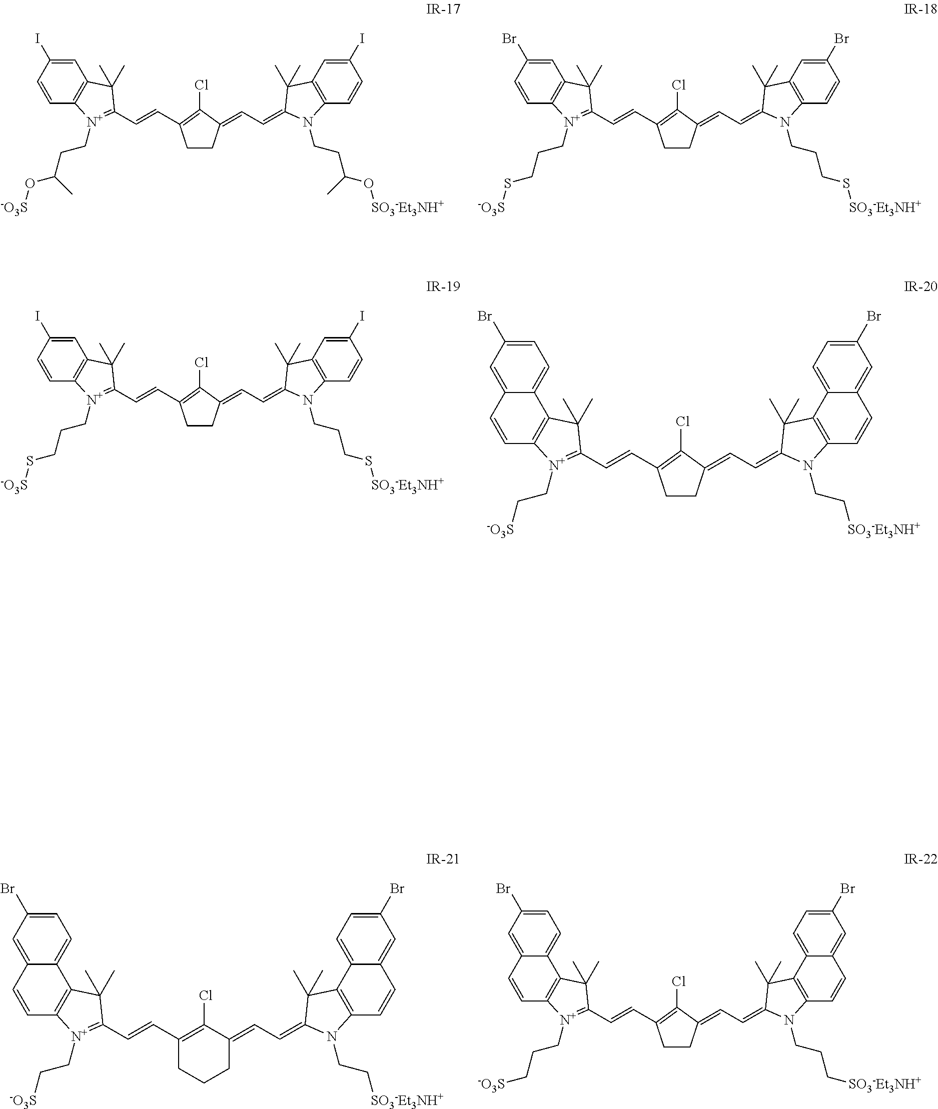

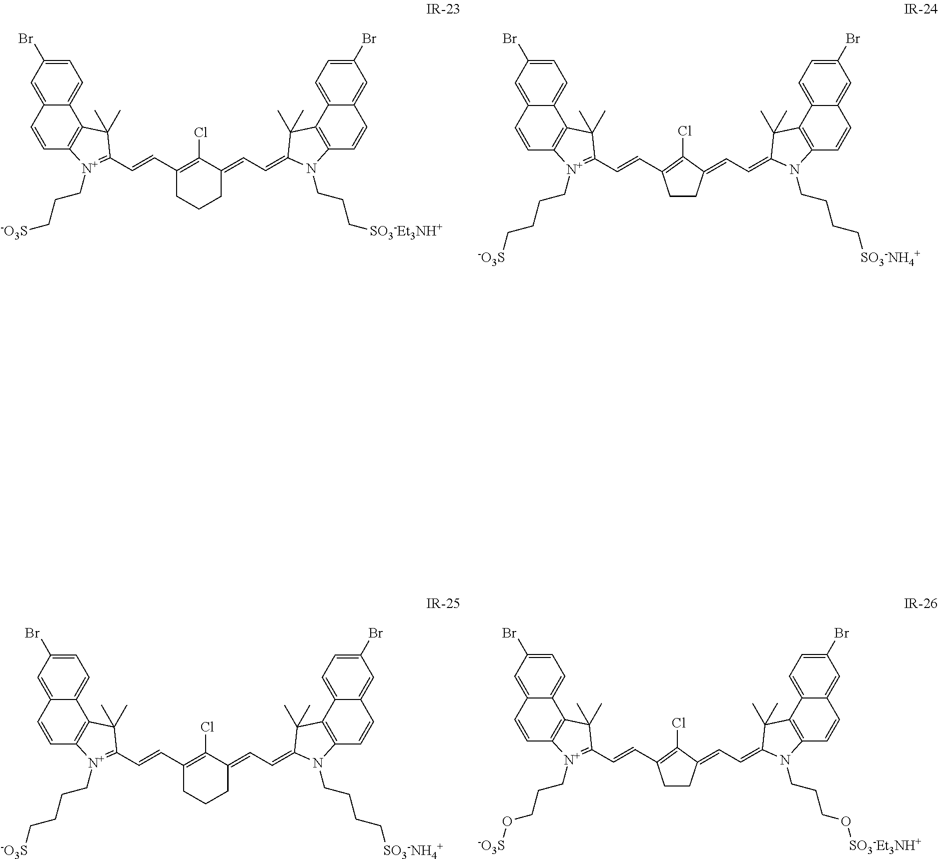

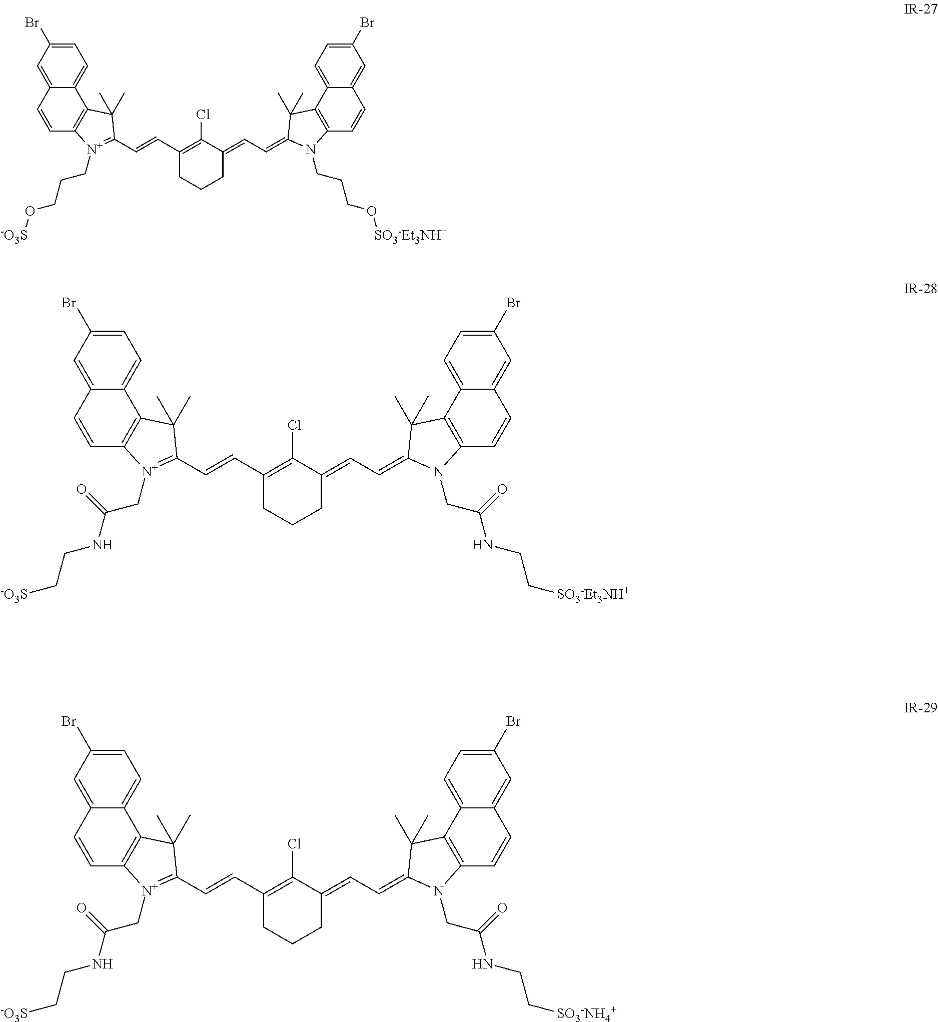

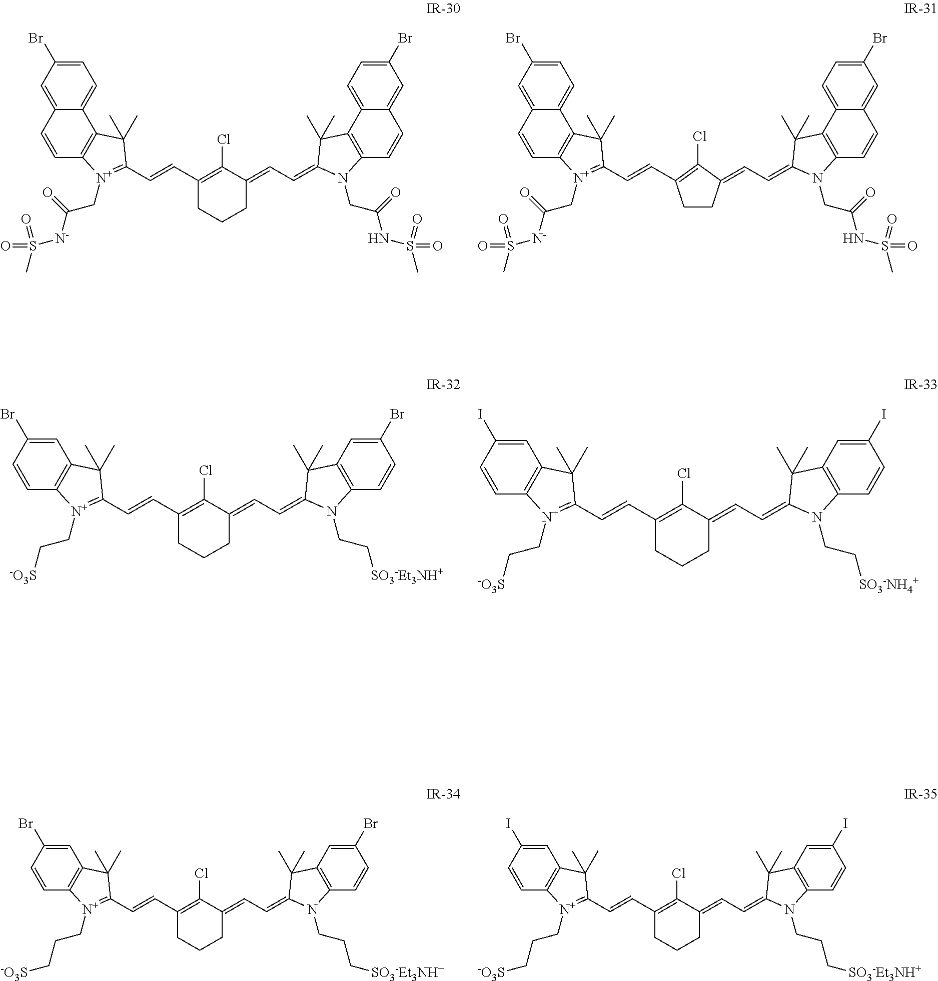

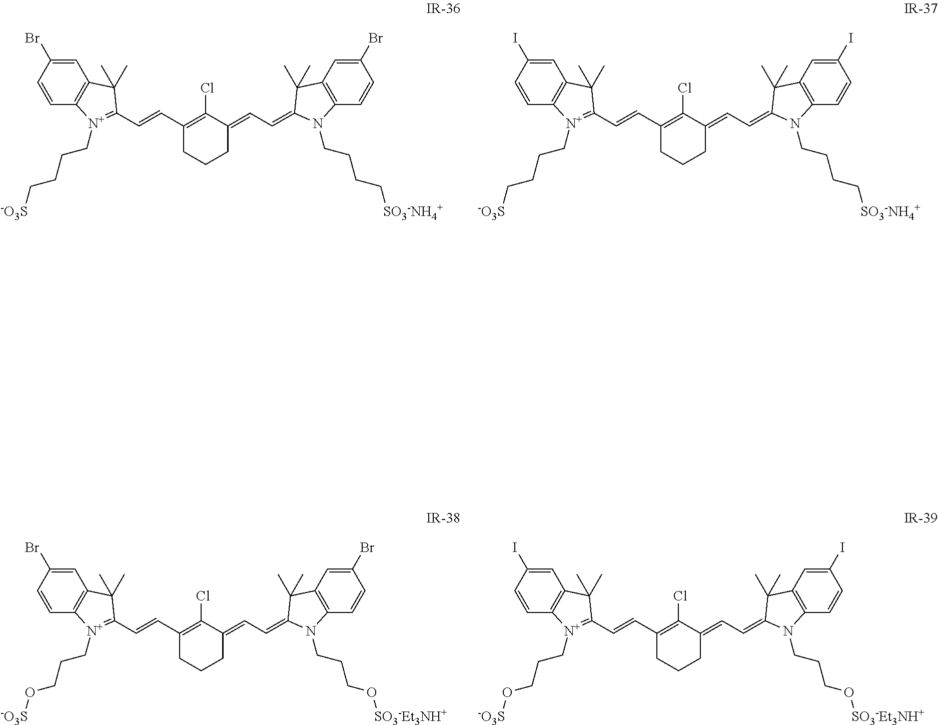

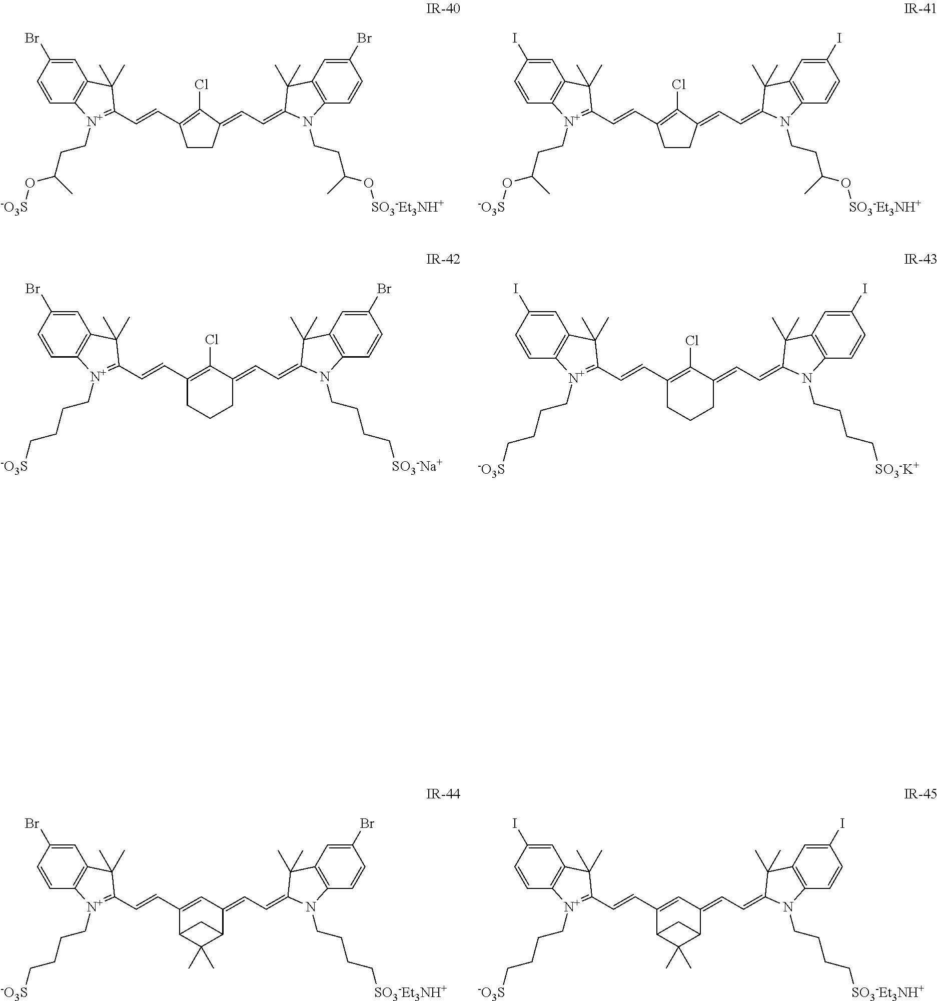

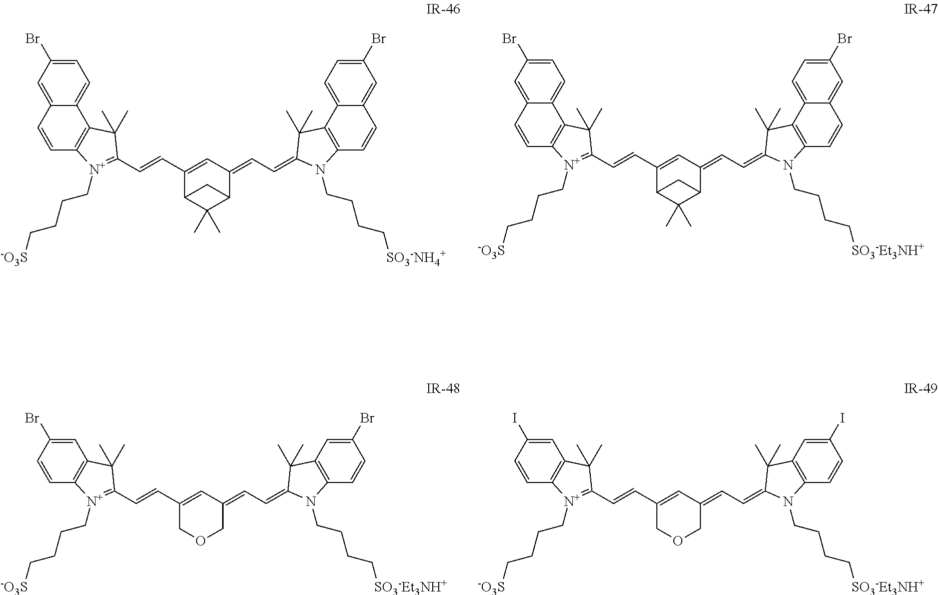

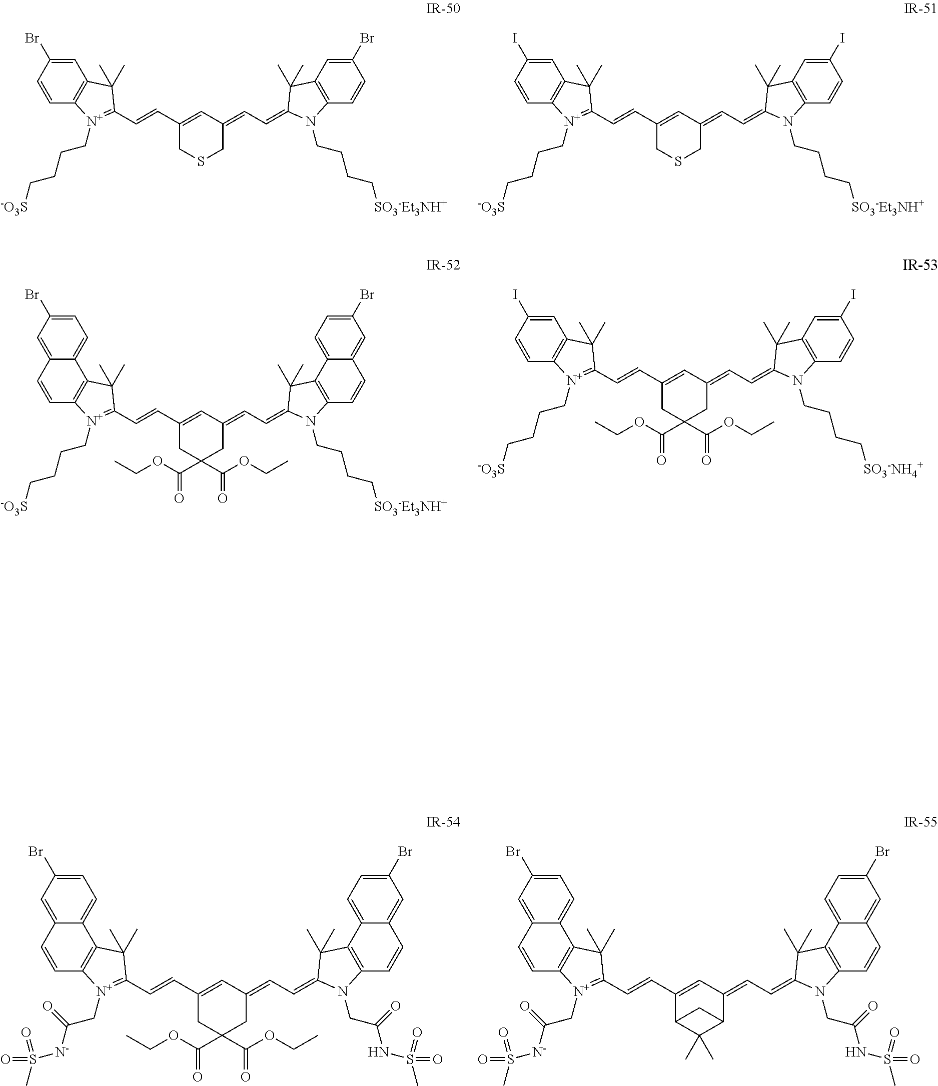

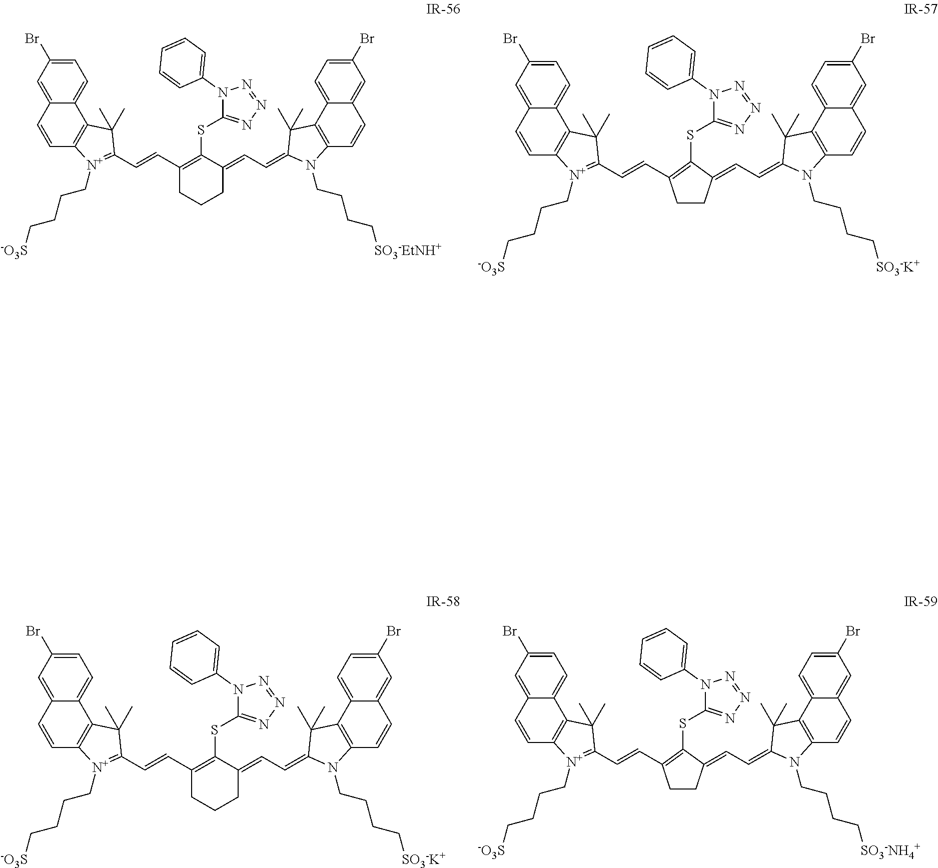

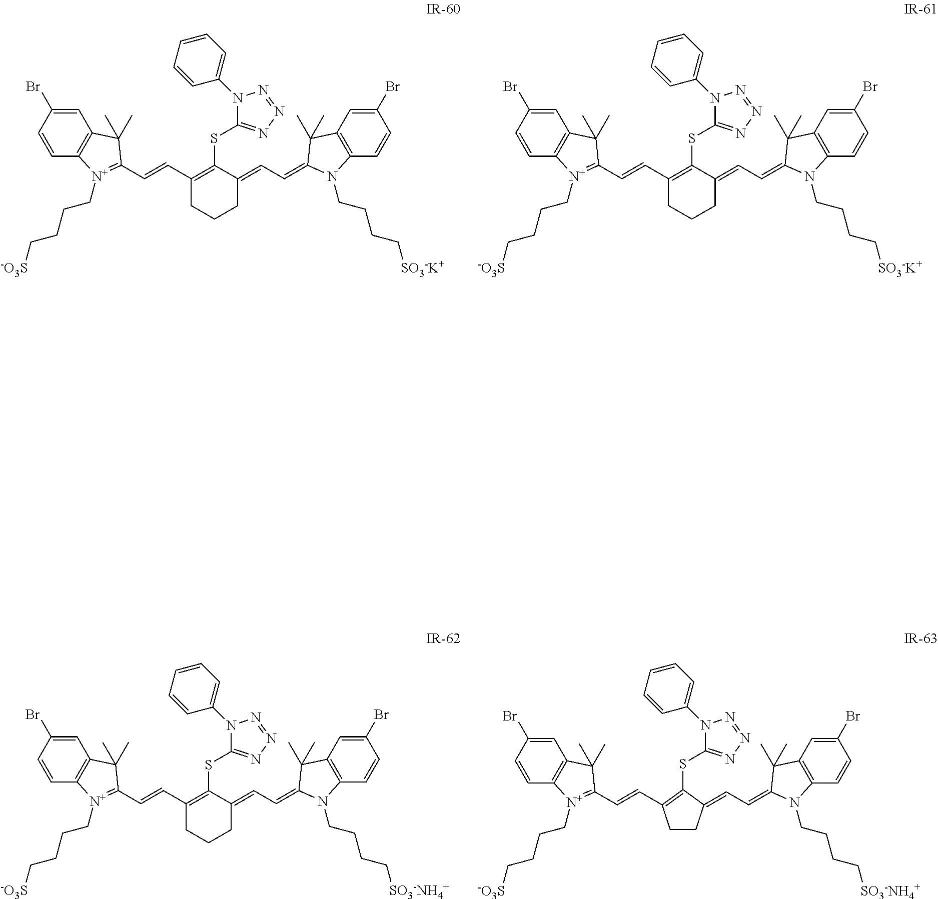

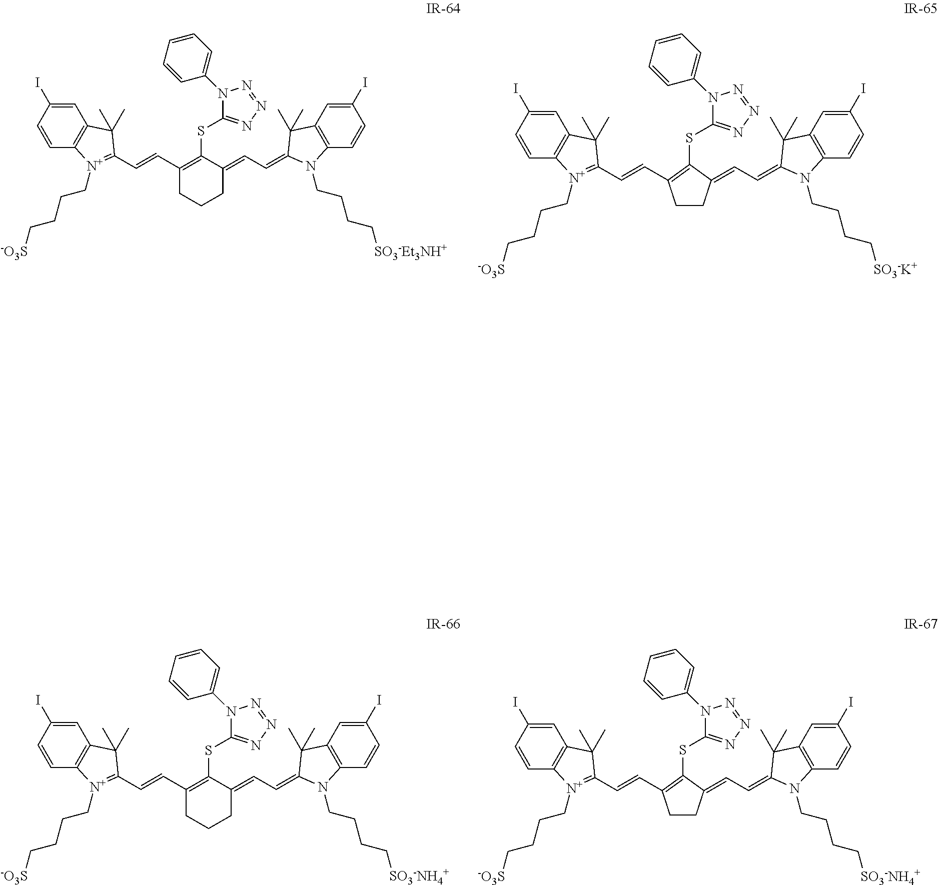

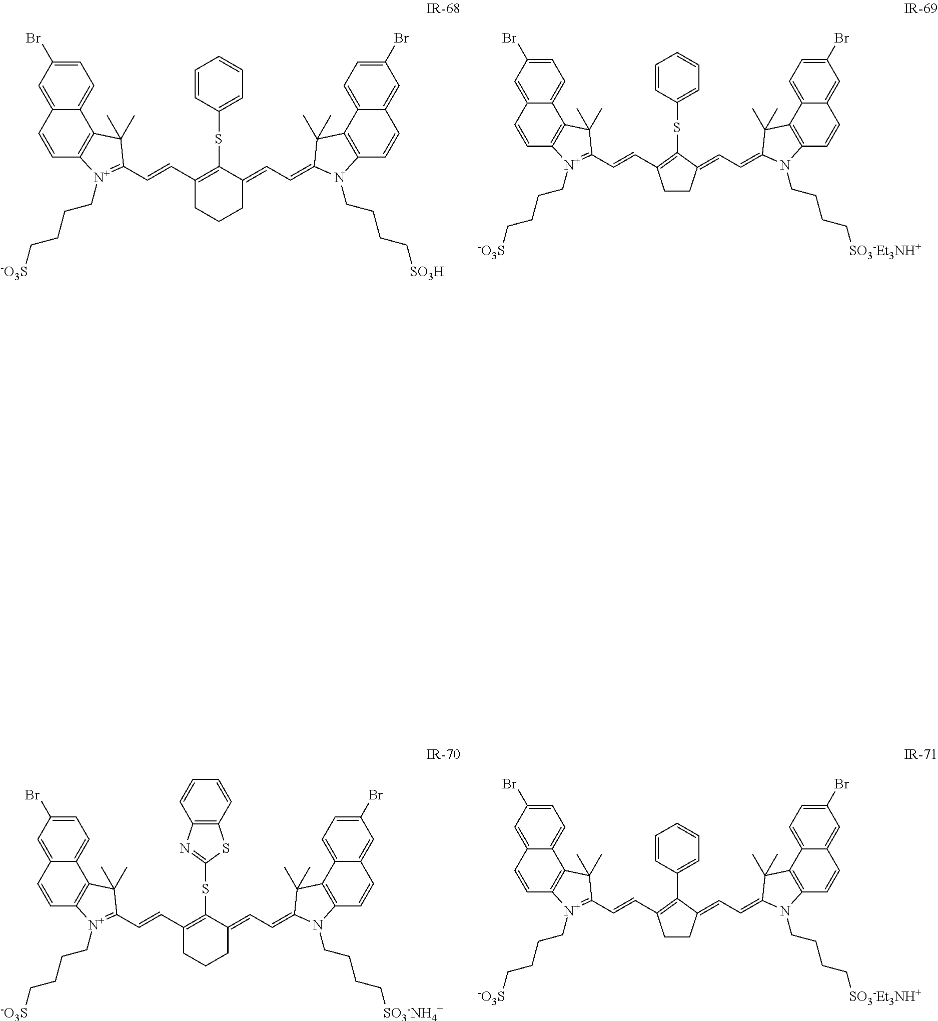

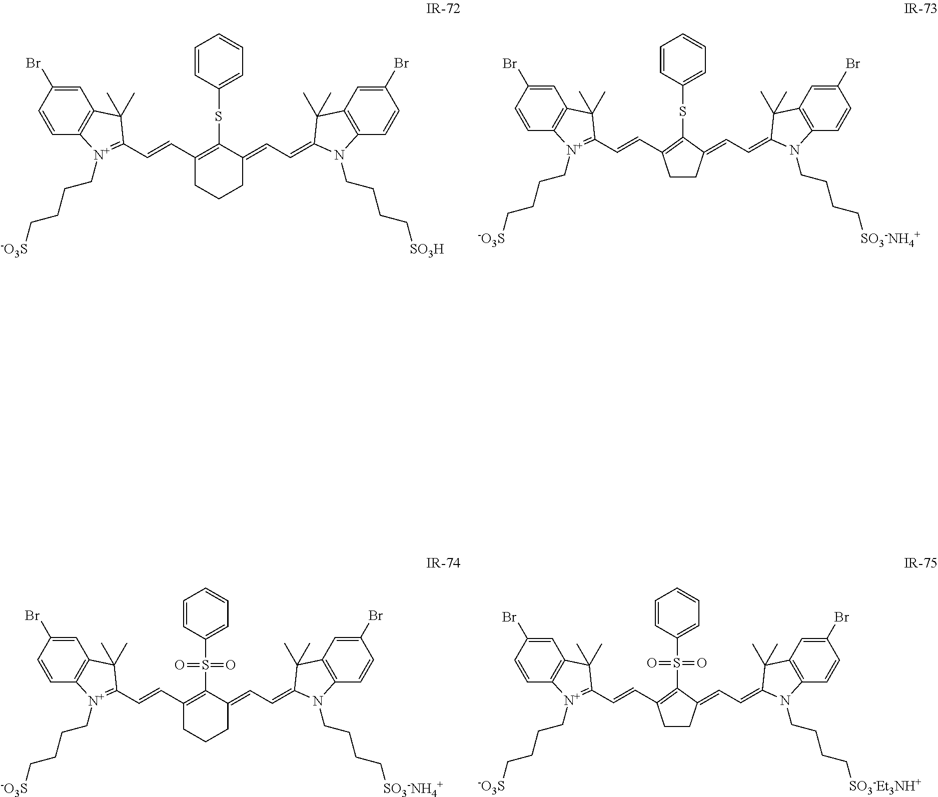

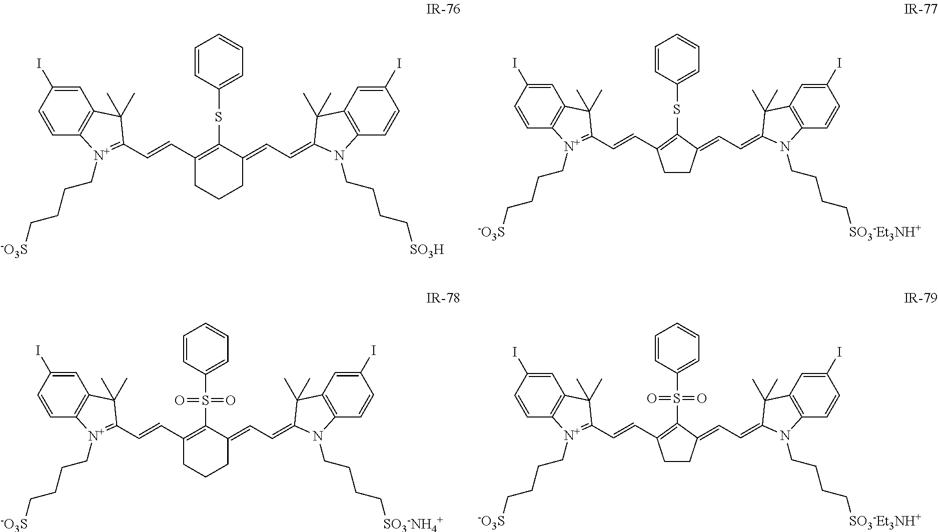

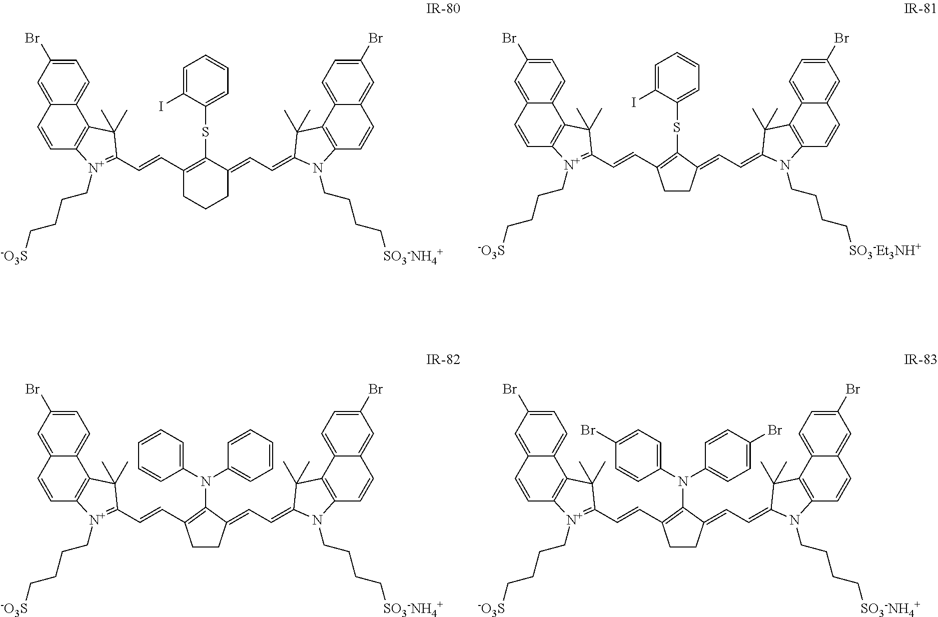

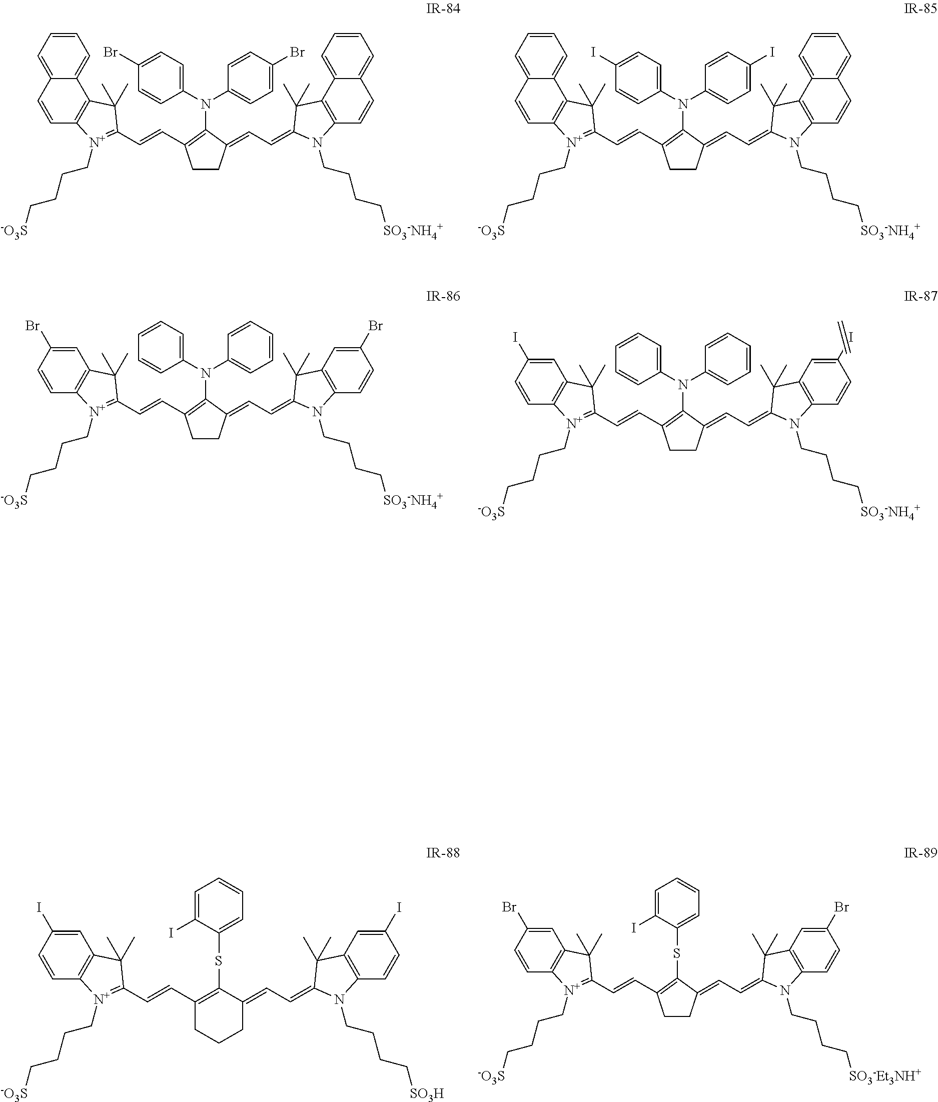

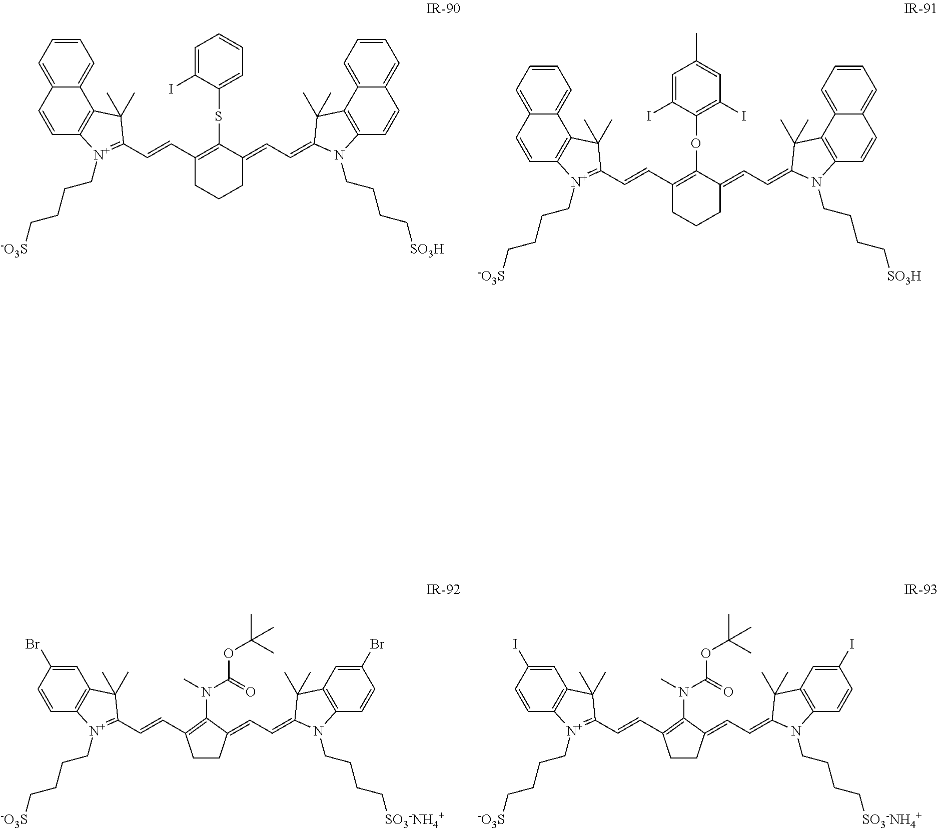

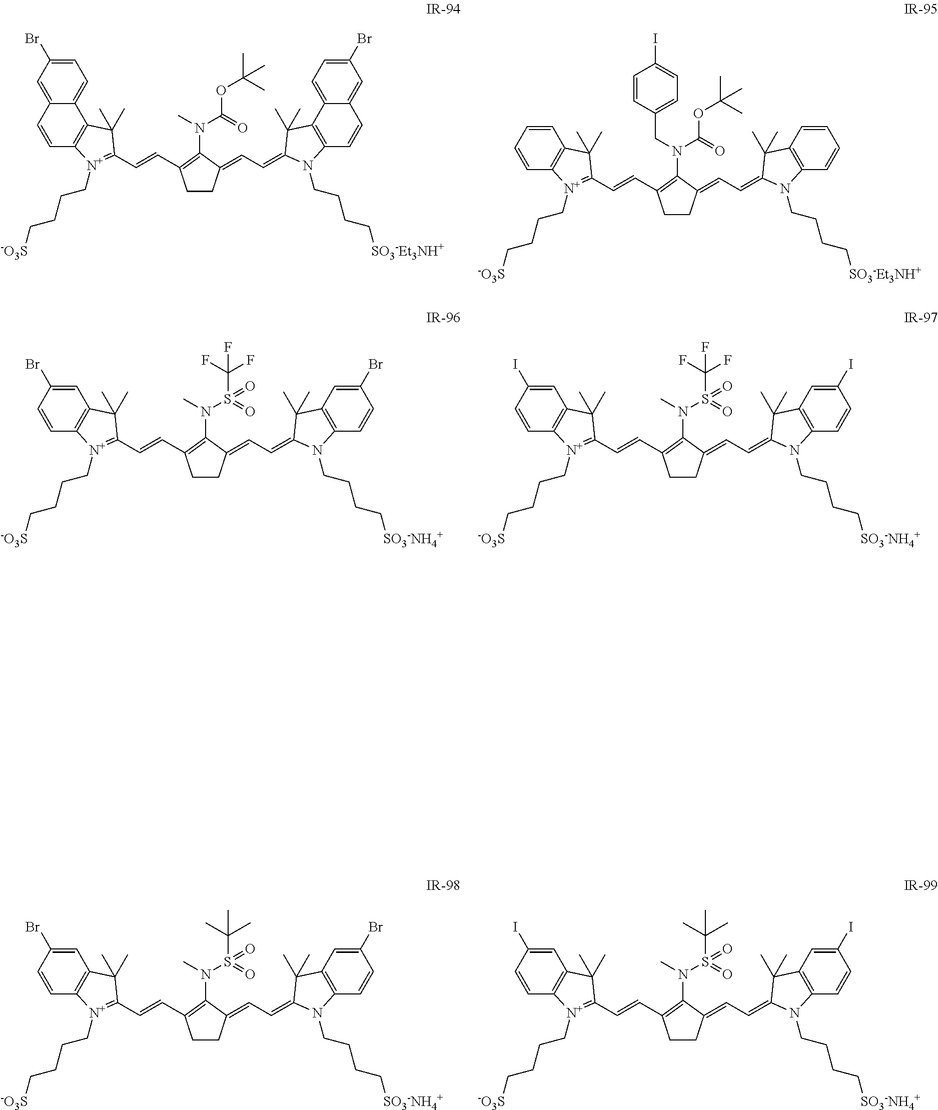

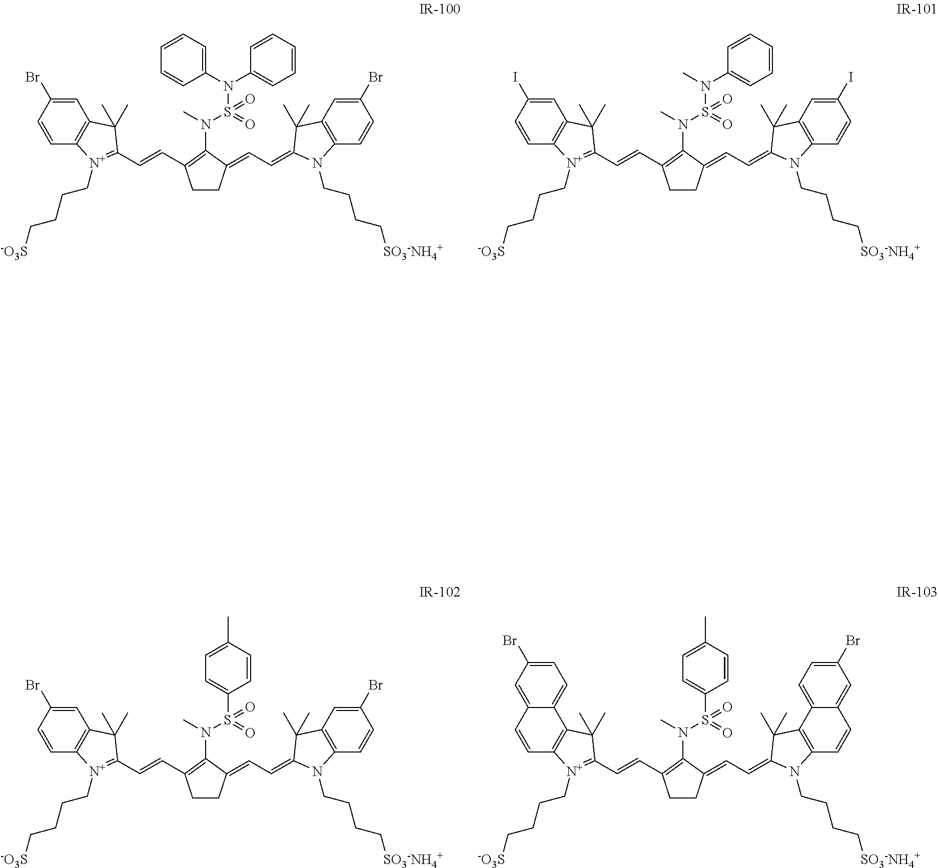

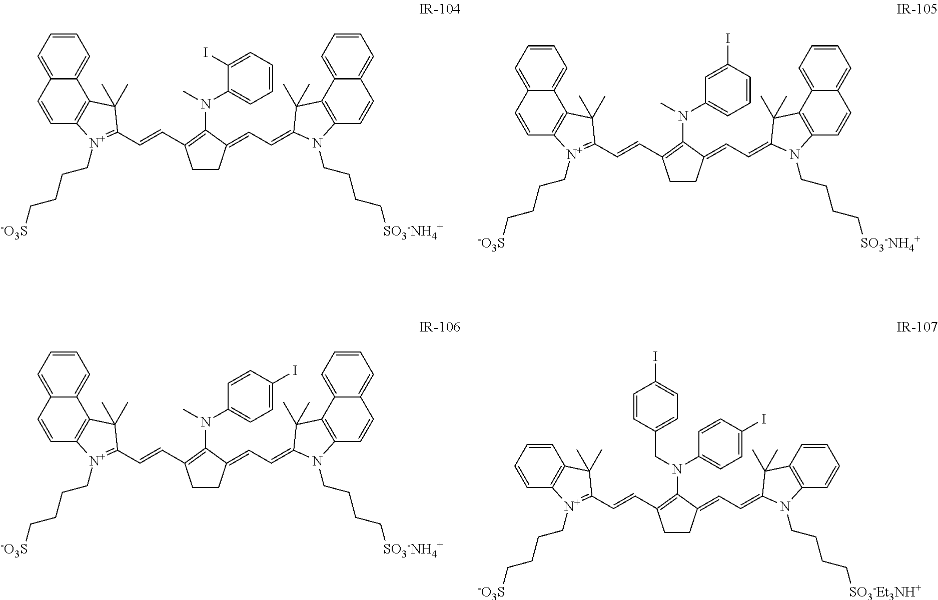

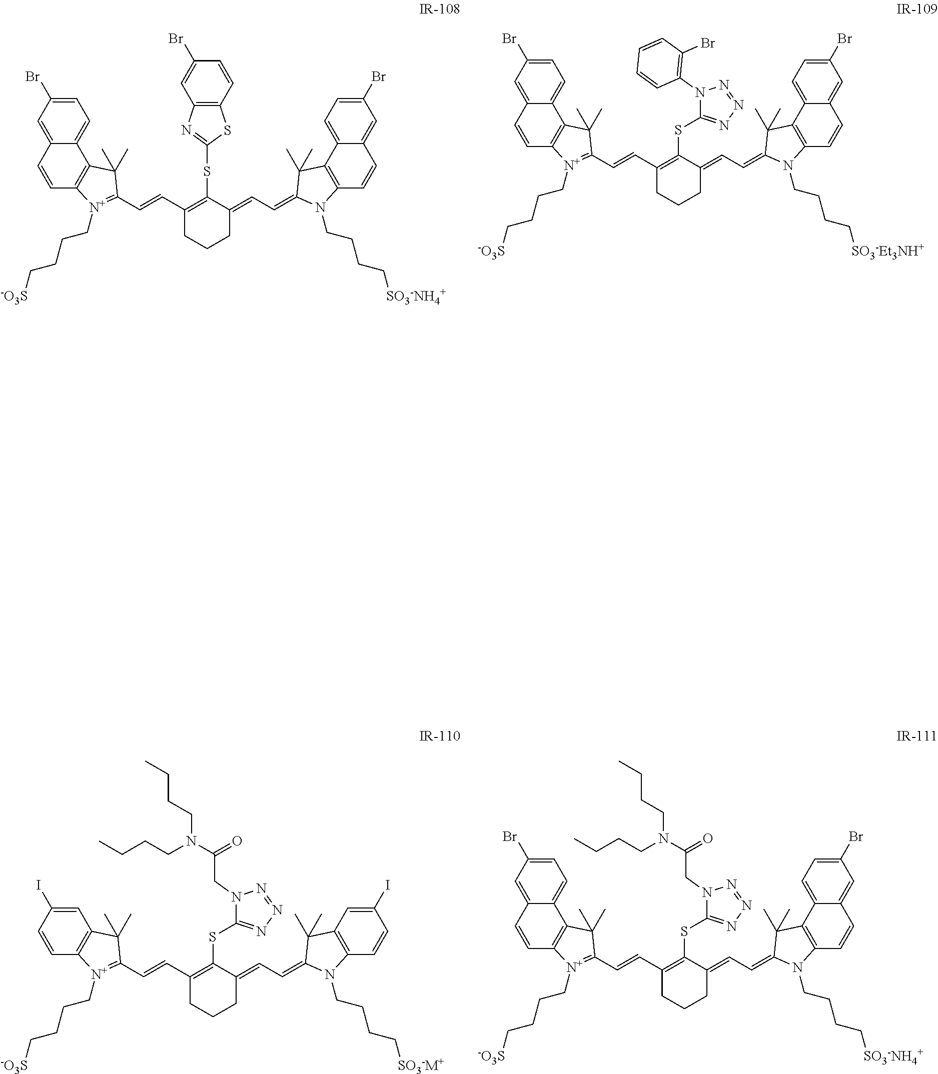

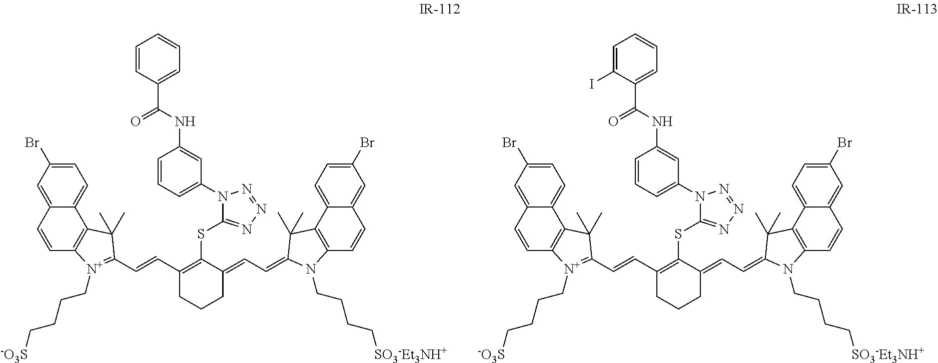

### Thermoplastic Particles

The thermoplastic particles preferably have an average particle diameter from 15 nm to 75 nm, more preferably from 20 to 55 nm, most preferably from 25 nm to 40 nm. The average particle diameter referred to in the claims and the description of this application is meant to be the average particle diameter measured by Photon Correlation Spectrometry, also known as Quasi-Elastic or Dynamic Light-Scattering, unless otherwise specified. The measurements were performed according the ISO 13321 procedure (first edition, 1996-07-01) with a Brookhaven BI-90 analyzer, commercially available from Brookhaven Instrument Company, Holtsville, N.Y., USA.

The amount of thermoplastic polymer particles is preferably at least 50, more preferably at least 60, most preferably at least 70% by weight relative to the total weight of all the ingredients in the image-recording layer. The thermoplastic polymer particles which are present in the coating may be selected from polyethylene, poly(vinyl)chloride, polymethyl(meth)acrylate, polyethyl (meth)acrylate, polyvinylidene chloride, poly(meth)acrylonitrile, polyvinylcarbazole, polystyrene or copolymers thereof.

According to a preferred embodiment, the thermoplastic polymer particles comprise polystyrene or derivatives thereof, mixtures comprising polystyrene and poly(meth)acrylonitrile or derivatives thereof, or copolymers comprising styrene and (meth)acrylonitrile or derivatives thereof. The latter copolymers may comprise at least 30% by weight of polystyrene, more preferably at least 50% by weight of polystyrene. In order to obtain sufficient resistivity towards organic chemicals such as hydrocarbons used in e.g. plate cleaners, the thermoplastic polymer particles preferably comprise at least 5% by weight, more preferably at least 30% by weight, of nitrogen containing units, such as (meth)acrylonitrile, as described in EP-A 1 219 416. According to the most preferred embodiment, the thermoplastic polymer particles consist essentially of styrene and acrylonitrile units in a weight ratio between 1:1 and 5:1 (styrene:acrylonitrile), e.g. in a 2:1 ratio.

The thermoplastic polymer particles may also comprise polymers or copolymers rendering the particles self-dispersible in an aqueous solution as for example disclosed in EP-As 1 834 764 and 1 157 829.

The thermoplastic polymer particles comprise preferably a polymer or co-polymer having a weight average molecular weight ranging from 5,000 to 1,000,000 g/mol.

The thermoplastic polymer particles can be prepared by addition polymerization or by condensation polymerization. They are preferably applied onto the lithographic base as dispersions in an aqueous coating liquid. These water based dispersions can be prepared by polymerization in a water-based system e.g. by free-radical emulsion polymerization as described in U.S. Pat. No. 3,476,937 or EP-A 1 217 010, or by a dispersing techniques of the water-insoluble polymers into water. Another method for preparing an aqueous dispersion of the thermoplastic polymer particles comprises (1) dissolving the hydrophobic thermoplastic polymer in an organic water immiscible solvent, (2) dispersing the thus obtained solution in water or in an aqueous medium and (3) removing the organic solvent by evaporation. The thermoplastic particles are preferably prepared by an emulsion polymerization. Emulsion polymerization is typically carried out through controlled addition of several components—i.e. vinyl monomers, surfactants (dispersion aids), initiators and optionally other components such as buffers or protective colloids—to a continuous medium, usually water. The resulting polymer of the emulsion polymerization is a dispersion of discrete particles in water. The surfactants or dispersion aids which are present in the reaction medium have a multiple role in the emulsion polymerization: (1) they reduce the interfacial tension between the monomers and the aqueous phase, (2) they provide reaction sites through micelle formation in which the polymerization occurs and (3) they stabilize the growing polymer particles and ultimately the latex emulsion. The surfactants are adsorbed at the water/polymer interface and thereby prevent coagulation of the fine polymer particles. A wide variety of surfactants are used for the emulsion polymerisation. In general, a surfactant molecule contains both polar (hydrophilic) and non-polar (hydrophobic or lipophilic) groups. The most used surfactants are anionic or non-ionic surfactants. Widely used anionic surfactants are, alkylsulfates, alkyl ether sulfates, alkyl ether carboxylates, alkyl or aryl sulfonates, alkyl phosphates or alkyl ether phosphates. An example of an alkyl sulfate surfactant is sodium lauryl sulfate (e.g. Texapon K12 by the company Cognis). An example of an alkyl ether sulfate surfactant is laureth-2 sulfate sodium salt (e.g. Empicol ESB form the company Huntsman). An example of an alkyl ether carboxylate is laureth-6 carboxylate (e.g. Akypo RLM45 from the company Kao Chemicals). An example of an alkyl ether phosphate is Trideceth-3 phosphate ester (e.g. Chemfac PB-133 from the company Chemax Inc.).

The critical micelle concentration (C.M.C.) of the used surfactants is an important property to control the particle nucleation and consequently the particle size and stabilization of the polymer particles. The C.M.C. can be varied by variation of the degree of ethoxylation of the surfactant. Alkyl ether sulfates having a different degree of ethoxylation are for example Empicol ESA (Laurette-1 sulfate sodium salt), Empicol ESB (Laurette-2 sulfate sodium salt) and Empicol ESC (Laurette-3 sulfate sodium salt). Alkyl ether carboxylates having a different degree of ethoxylation are for example Akypo RLM-25 (Laurette-4 carboxylic acid), Akypo RLM-45 (Laurette-6 carboxylic acid) and Akypo RLM-70 (Laurette-8 carboxylic acid). Alkyl ether phosphates having a different degree of ethoxylation are for example Chemfac PB-133 (Trideceth-3 phosphate ester, acid form), Chemfac PB-136 (Trideceth-6-phosphate ester, acid form) and Chemfac PB-139 (Trideceth-9-phosphate ester, acid form).

The carboxylate and phosphate ester surfactants are usually supplied in the acid form. In order to prepare an aqueous solution of these surfactants, a base such as NaOH, Na₂CO₃, NaHCO₃, NH₄OH, or NH₄HCO₃ must be added.

In a preferred embodiment, the thermoplastic particles are prepared by emulsion polymerization in the presence of a surfactant selected from alkyl phosphates and alkyl ether phosphates

### Binder

The image-recording layer may further comprise a hydrophilic binder. Examples of suitable hydrophilic binders are homopolymers and copolymers of vinyl alcohol, (meth)acrylamide, methylol (meth)acrylamide, (meth)acrylic acid, hydroxyethyl (meth)acrylate, maleic anhydride/vinylmethylether copolymers, copolymers of (meth)acrylic acid or vinylalcohol with styrene sulphonic acid. Preferably, the hydrophilic binder comprises polyvinylalcohol or polyacrylic acid.

The amount of hydrophilic binder may be between 2 and 30% by weight, preferably between 2 and 20% by weight, more preferably between 3 and 10% by weight relative to the total weight of all ingredients of the image-recording layer.

The amount of the hydrophobic thermoplastic polymer particles relative to the amount of the binder is preferably between 8 and 25, more preferably between 10 and 22, most preferably between 12 and 20.

### Contrast Dyes

Colorants, such as dyes or pigments, which provide a visible color to the coating and remain in the exposed areas of the coating after the developing step may be added to the coating. The image-areas, which are not removed during the developing step, form a visible image on the printing plate and inspection of the lithographic image on the developed printing plate becomes feasible. Typical examples of such contrast dyes are the amino-substituted tri- or diaryl-methane dyes. In a preferred embodiment, anionic tri- or diaryl-methane dyes are used. Dyes which, combined with specific additives, only slightly colour the coating but which become intensively coloured after exposure, as described in for example WO 2006/005688 are also of interest. Other preferred contrast dyes are those described in EP-A 1 914 069.

Typical contrast dyes may be combined, or even replaced by IR-dyes, capable of forming a visible colour upon exposure to IR radiation, as those described in EP-As 1 736 312 and 1 910 082 or, more preferably, by the IR-dyes capable of forming a visible colour upon exposure to IR radiation according to a preferred embodiment of the present invention, as described above on page 11 and 12.

### Other Ingredients

Optionally, the coating may further contain additional ingredients. These ingredients may be present in the image-recording layer or in an optional other layer. For example, additional binders, polymer particles such as matting agents and spacers, surfactants such as perfluoro-surfactants, silicon or titanium dioxide particles, development inhibitors, development accelerators, colorants, metal complexing agents are well-known components of lithographic coatings.

Preferably the image-recording layer comprises an organic compound, characterised in that the organic compound comprises at least one phosphoric acid group or at least one phosphoric acid group or a salt thereof, as described in WO 2007/045515.

To avoid degradation of the IR-dye, for example upon exposure of the precursor to daylight, a light stabilizer or anti-oxidant may be present in the coating. Preferred stabilizers, such as ascorbic or isoascorbic acid derivatives, are disclosed in the unpublished EP-A 07 104 991.0 (filed on 2007-03-27).

### Other Layers of the Coating

To protect the surface of the coating, in particular from mechanical damage, a protective layer may optionally be applied on the image-recording layer. The protective layer generally comprises at least one water-soluble polymeric binder, such as polyvinyl alcohol, polyvinylpyrrolidone, partially hydrolyzed polyvinyl acetates, gelatin, carbohydrates or hydroxyethylcellulose. The protective layer may contain small amounts, i.e. less then 5% by weight, of organic solvents.

The IR-dyes mentioned above may be present in the image-recording layer or in the protective layer, or in both.

The thickness of the protective layer is not particularly limited but preferably is up to 5.0 μm, more preferably from 0.05 to 3.0 μm, particularly preferably from 0.10 to 1.0 μm.

The coating may further contain other additional layer(s) such as for example an adhesion-improving layer located between the image-recording layer and the support.

The coating may be applied on the support by any coating technique known in the art. After applying the coating, the applied layer(s) are dried as commonly known in the art. While drying the coating, in particular the image-recording layer, it is preferred to keep the temperature, measured as the wet coating temperature, below 45° C., more preferably below 40° C., most preferably below 35° C. and to keep the temperature, measured as the dry coating temperature, below 90° C., more preferably below 60° C.

### Support

The support of the lithographic printing plate precursor has a hydrophilic surface or is provided with a hydrophilic layer. The support may be a sheet-like material such as a plate or it may be a cylindrical element such as a sleeve which can be slid around a print cylinder of a printing press.

In one embodiment of the invention the support is a metal support such as aluminum or stainless steel. The support can also be a laminate comprising an aluminum foil and a plastic layer, e.g. polyester film. A particularly preferred lithographic support is an aluminum support. Any known and widely used aluminum materials can be used. The aluminum support has a thickness of about 0.1-0.6 mm. However, this thickness can be changed appropriately depending on the size of the printing plate used and the plate-setters on which the printing plate precursors are exposed.

To optimize the lithographic properties, the aluminum support is subjected to several treatments well known in the art such as for example: degrease, surface roughening, etching, anodization, sealing, surface treatment. In between such treatments, a neutralization treatment is often carried out. A detailed description of these treatments can be found in e.g. EP-As 1 142 707, 1 564 020 and 1 614 538.

A preferred aluminum substrate, characterized by an arithmetical mean center-line roughness Ra less then 0.45μ is described in EP 1 356 926. Optimizing the pore diameter and distribution thereof of the grained and anodized aluminum surface as described in EP 1 142 707 and U.S. Pat. No. 6,692,890 may enhance the press life of the printing plate and may improve the toning behaviour. Avoiding large and deep pores as described in U.S. Pat. No. 6,912,956 may also improve the toning behaviour of the printing plate. An optimal ratio between pore diameter of the surface of the aluminum support and the average particle size of the thermoplastic particles may enhance the press run length of the plate and may improve the toning behaviour of the prints. This ratio of the average pore diameter of the surface of the aluminum support to the average particle size of the thermoplastic particles present in the image-recording layer of the coating, preferably ranges from 0.1 to 0.8, more preferably from 0.2 to 0.5.

Treatments of a grained and anodized aluminum surface are often referred to as post-anodic treatments. Preferred post-anodic treatments are the application of polyvinylphosphonic acid or derivatives thereof, of polyacrylic acid, of potassium fluorozirconate or a phosphate, of an alkali metal silicate, or combinations thereof, applied together or sequential to the surface of a grained and anodized aluminum support. Preferred combinations of treatments are disclosed in the unpublished EP-As 07 104 472.1 (filed on 2007 Mar. 20) and 07 105 315.1 (filed on 2007 Mar. 30).

It has been observed that when using the IR-dyes according to a preferred embodiment of the present invention, a grained and anodized aluminum support without any post-anodic treatment may be used. It has been observed that when using such a support a higher sensitivity of the precursor and especially a higher press run length with the obtained plate may be realized. When using such a support without any post-anodic treatment, it is preferred to develop the exposed precursor in an alkaline aqueous solution to ensure a sufficient clean-out behaviour.

Alternative supports for the plate precursor can also be used, such as amorphous metallic alloys (metallic glasses). Such amorphous metallic alloys can be used as such or joined with other non-amorphous metals such as aluminum. Examples of amorphous metallic alloys are described in U.S. Pat. No. 5,288,344, U.S. Pat. No. 5,368,659, U.S. Pat. No. 5,618,359, U.S. Pat. No. 5,735,975, U.S. Pat. No. 5,250,124, U.S. Pat. No. 5,032,196, U.S. Pat. No. 6,325,868, and U.S. Pat. No. 6,818,078. The following references describe the science of amorphous metals in much more detail and are incorporated as references: Introduction to the Theory of Amorphous Metals, N. P. Kovalenko et al. (2001); Atomic Ordering in Liquid and Amorphous Metals, S. I. Popel, et al; Physics of Amorphous Metals, N. P. Kovalenko et al (2001).

According to another embodiment, the support can also be a flexible support, which is provided with a hydrophilic layer. The flexible support is e.g. paper, plastic film, thin aluminum or a laminate thereof. Preferred examples of plastic film are poly-ethylene terephthalate film, polyethylene naphthalate film, cellulose acetate film, polystyrene film, polycarbonate film, etc. The plastic film support may be opaque or transparent. Particular examples of suitable hydrophilic layers that may be supplied to a flexible support for use in accordance with a preferred embodiment of the present invention are disclosed in EP-A 601 240, GB 1 419 512, FR 2 300 354, U.S. Pat. No. 3,971,660, U.S. Pat. No. 4,284,705, EP 1 614 538, EP 1 564 020 and US 2006/0019196.

### Exposure

Preferably, the printing plate precursor is imagewise exposed with infrared radiation, preferably near infrared radiation. The infrared radiation is converted into heat by an IR-dye as discussed above. The heat-sensitive lithographic printing plate precursor of a preferred embodiment of the present invention is preferably not sensitive to visible radiation. Most preferably, the coating is not sensitive to ambient daylight, i.e. visible (400-750 nm) and near UV radiation (300-400 nm) at an intensity and exposure time corresponding to normal working conditions so that the material can be handled without the need for a safe light environment.

The printing plate precursors of a preferred embodiment of the present invention can be exposed to infrared radiation by e.g. LEDs or an infrared laser. Preferably lasers, emitting near infrared radiation having a wavelength in the range from about 700 to about 1500 nm, e.g. a semiconductor laser diode, a Nd:YAG or a Nd:YLF laser, are used. Most preferably, a laser emitting in the range between 780 and 830 nm is used. The required laser power depends on the sensitivity of the image-recording layer, the pixel dwell time of the laser beam, which is determined by the spot diameter (typical value of modern plate-setters at 1/e² of maximum intensity: 10-25 μm), the scan speed and the resolution of the exposure apparatus (i.e. the number of addressable pixels per unit of linear distance, often expressed in dots per inch or dpi; typical value: 1,000-4,000 dpi).

In a preferred embodiment of this invention a useful lithographic image is obtained upon image-wise exposure of the printing plate precursor with IR radiation having an energy density, measured at the surface of the precursor, of 200 mJ/cm² or less, more preferably of 180 mJ/cm² or less, most preferably of 160 mJ/cm² or less. With a useful lithographic image on the printing plate, 2% dots (at 200 lpi) are perfectly visible on at least 1 000 prints on paper.

Two types of laser-exposure apparatuses are commonly used: internal (ITD) and external drum (XTD) platesetters. ITD platesetters for thermal plates are typically characterized by a very high scan speed up to 1500 m/sec and may require a laser power of several Watts. The Agfa GALILEO T (trademark of Agfa Graphics N.V.) is a typical example of a platesetter using the ITD-technology. XTD platesetters for thermal plates having a typical laser power from about 20 mW to about 500 mW per laser beam operate at a lower scan speed, e.g. from 0.1 to 20 m/sec. The Agfa XCALIBUR, ACCENTO, AVALON and AVALON N platesetter families (trademark of Agfa Graphics N.V.) make use of the XTD-technology.

Due to the heat generated during the exposure step, the thermoplastic polymer particles may fuse or coagulate thereby forming a hydrophobic phase which corresponds to the printing areas of the printing plate. Coagulation may result from heat-induced coalescence, softening or melting of the thermoplastic polymer particles. There is no specific upper limit to the coagulation temperature of the thermoplastic polymer particles, however the temperature should be sufficiently below the decomposition temperature of the polymer particles. Preferably the coagulation temperature is at least 10° C. below the temperature at which the decomposition of the polymer particles occurs. The coagulation temperature is preferably higher than 50° C., more preferably above 100° C.

As an alternative, the printing plate precursor may be imagewise heated by a heating element to form an image.

### Development

In one embodiment of the invention the printing plate precursor, after exposure, is developed off-press by a suitable processing liquid. In the development step, the non-exposed areas of the image-recording layer are at least partially removed without essentially removing the exposed areas, i.e. without affecting the exposed areas to an extent that renders the ink-acceptance of the exposed areas unacceptable. The processing liquid can be applied to the plate e.g. by rubbing with an impregnated pad, by dipping, immersing, (spin-)coating, spraying, pouring-on, either by hand or in an automatic processing apparatus. The developed plate precursor can, if required, be post-treated with rinse water, a suitable correcting agent or a preservative as known in the art.

The developing step with the processing liquid is preferably combined with mechanical rubbing, preferably by one, two or more rotating brushes, to better remove the non-images parts of the precursor. Preferred rotating brushes are described in US 2007/0184387 (paragraphs [0255] to [0257]).

Development is preferably carried out by spraying the developing solution onto the precursor, i.e. spray development, or by dipping the precursor into the developing solution. Preferably, the development is carried out in an automatic processor equipped with supplying device for the developer and rubbing members. Spray development involves spraying a developing solution on the plate precursor, for example with one or more spray bars. Dip development involves immersion of the plate into a developing solution. The development may be a batch development, i.e. development is carried out with a batch of developer until development is no longer sufficient. At that moment a new batch of developer is introduced in the processor. Development may also be carried out with regeneration of the developer, whereby a given amount of fresh developer is added to the development solution as function of the number of plates already developed. The composition and/or concentration of the fresh developer added during regeneration may be the same or different to that of the initial developer.

During the development step, any water-soluble protective layer present is also removed. A protective overcoat may also be removed by carrying out a pre-wash before development.

According to a preferred embodiment the processing liquid used in the off-press development is an aqueous solution having a pH from 2 to 10, preferably from 3 to 9, more preferably from 4 to 8. Particularly preferred, the aqueous solution is a gum solution. A gum solution is essentially an aqueous solution comprising a surface protective compound capable of protecting the lithographic image of a printing plate against contamination. Suitable examples of such compounds are film-forming hydrophilic polymers or surfactants. When using a gum solution as developing solution, in the development step in the method according to a preferred embodiment of the present invention the non-image areas of the precursor are removed and, in addition, a protective layer is provided on the developed printing plate. A layer that remains on the plate after development with the gum solution preferably comprises more than 0.01 g/m² of a surface protective compound.

The gum solution may be supplied as a ready-to-use developer or as a concentrated solution, which is diluted by the end user with water to a ready-to-use developer according to the instructions of the supplier: typically 1 part of the gum is diluted with 1 to 10 parts of water.

A preferred composition of the gum solution is disclosed in WO 2005/111727 (page 6, line 5 to page 11, line 35) and EP-A 1 621 339 (paragraphs [0014] to [0061]).

Preferred surfactants are for example block copolymers based on ethylene oxide and propylene oxide such as the commercially available PLURONIC® surfactants such as Pluronic 9400. Other preferred surfactants are tristyrylphenol ethoxylates such as the EMULSOGEN® surfactants, for example Emulsogen TS160 or TS200. Highly preferred, a combination of both these surfactants is used.

Besides the surface protective compound the gum solution preferably comprises a salt formed by reaction of an acid, selected from phosphoric acid and phosphorous acid, with a di- or tri-alkanolamine as disclosed in the unpublished WO 2008/055872 (filed on 2008 May 14).

When the time between the preparation of the printing plate and mounting that printing plate on a press to start printing is sufficiently short so that no severe contamination may take place, development may be carried out with any aqueous solution having preferably a pH between 2 and 10, even plain water. Also commonly used press room chemicals, for example fountain solutions or aqueous plate cleaners and/or conditioners may be used, if necessary after proper dilution.

According to another preferred embodiment the processing liquid used in the off-press development is an alkaline aqueous solution having a pH of at least 9, preferably at least 10, more preferably at least 11 and most preferably at least 12. The developer comprises an alkaline agent. In a preferred embodiment the alkaline agent comprises an alkaline silicate or metasilicate. The alkaline silicate or metasilicate exhibits an alkalinity when dissolved in water, and examples thereof include an alkali metal silicate and alkali metal metasilicate such as sodium silicate, sodium metasilicate, potassium silicate and lithium silicate, and ammonium silicate. The alkaline silicate may be used alone, or in combination with another alkaline agent. The development performance of the alkaline aqueous solution may be easily modulated by adjusting the molar ratio of alkaline silicates and alkali metal hydroxides, represented by silicon oxide (SiO₂) and alkali oxide (M₂O, wherein M represents an alkali metal or an ammonium group). The alkaline aqueous solution has preferably a molar ratio SiO₂/M₂O from 0.5 to 3.0, more preferably from 1.0 to 2.0, most preferably of 1.0. The concentration of alkaline silicate in the developer ranges generally from 1 to 14 weight %, preferably from 3 to 14 weight %, and more preferably from 4 to 14% weight %.

In another embodiment, the aqueous alkaline solution may comprise a nonreducing sugar. The nonreducing sugar denotes sugars having no reductive property due to the absence of a free aldehyde group or a free ketone group. The nonreducing sugar is classified into trehalose-type oligosaccharides wherein a reductive group and another reductive group make a linkage; glycosides wherein a reductive group in a sugar is linked to a non-sugar compound; and sugar alcohols which are produced by reducing a sugar with hydrogenation. The trehalose-type oligosaccharides include sucrose and trehalose, and the glycosides include alkyl glycosides, phenol glycosides, mustard oil glycosides and the like. The sugar alcohols include D,L-arabitol, ribitol, xylitol, D,L-sorbitol, D,L-mannitol, D,L-iditol, talitol, dulcitol, allodulcitol and the like. Further, maltitol obtained by hydrogenation of disaccharide, a reduced material obtained by hydrogenation of oligosaccharide (a reduced starch syrup) and the like are preferably used. Pentaerythritol can also be used in the developing solution.

Of the above mentioned nonreducing sugars, preferred are sugar alcohols and sucrose, and particularly preferred are D-sorbitol, sucrose and a reduced starch syrup, since they have buffering action in appropriate pH range.

In addition to alkali metal silicates and/or nonreducing sugars, the developer may optionally contain further components, such as buffer substances, complexing agents, antifoam agents, organic solvents in small amounts, corrosion inhibitors, dyes, surfactants and/or hydrotropic agents as known in the art.

A preferred developer solution is an aqueous alkaline solution comprising at least 0.05 g/l of lithium ions, as disclosed in the unpublished EP-A 08 102 122.2 (filed on 2008 Feb. 28). The lithium ions may be introduced in the developer by adding a lithium salt to the developer. The lithium ions may be added in the form of organic salts like for example lithium benzoate, lithium citrate or lithium acetate. Preferably, the lithium ions are introduced in the developer by inorganic salts. Suitable inorganic lithium salts include lithium chloride, lithium perchlorate, lithium bromide, lithium tetraborate, lithium phosphate, lithium silicates, lithium nitrate, lithium hydroxide, lithium carbonate and lithium sulfate. The lithium may be introduced in the developer by one lithium salt or by two or more different lithium salts. In a preferred embodiment, the aqueous alkaline solution further comprises a mono alkali metal or ammonium salt of an organic carboxylic acid, having 4 to 12 carbon atoms and substituted with 3 to 11 hydroxyl groups. The organic carboxylic acid is more preferably a sugar acid, i.e. a sugar compound having a carboxylic acid group. The sugar acids have preferably at least 3 hydroxyl groups, more preferably at least 4 hydroxyl groups, most preferably at least 5 hydroxyl groups. The sugar acids have preferably at most 11 hydroxyl groups, more preferably at most 7 hydroxyl groups, most preferably at most 6 hydroxyl groups. The sugar acids include gluconic acid, D-glucaric acid, pentaric acid, D-galacturonic acid, D-glucuronic acid, heptonic acid, D-gluco-heptonic acid, tartaric acid, erythronic acid, L-arabinoic acid, D-arabino-2-hexylosonic acid, glucopyranuronic acid and muramic acid. Preferred examples are gluconic acid, D-gluco-heptonic acid and L-arabinoic acid. Gluconic acid is highly preferred in the developing solution of a preferred embodiment of the present invention. It has been observed that the presence of a mono alkali metal or ammonium salt of an organic carboxylic acid, having 4 to 12 carbon atoms and substituted with 3 to 11 hydroxyl groups, in combination with the presence of the lithium ions in the developing solution may result in even better clean-out properties during the restart of the printing press. A preferred amount of the mono alkali metal or ammonium salt of an organic carboxylic acid, having 4 to 12 carbon atoms and substituted with 3 to 11 hydroxyl groups, for example of gluconic acid, is at least 0.025 mol/l, more preferably at least 0.04 mol/l, most preferably at least 0.08 mol/l. The molar ratio of lithium ions to gluconic acid, is preferably between 0.3 and 10.0, more preferably between 0.6 and 7.0, most preferably between 0.9 and 4.0.

For replenishment (also called regeneration) purposes, alkali metal silicate solutions having alkali metal contents of from 0.6 to 2.0 mol/l can suitably be used. These solutions may have the same silica/alkali metal oxide ratio as the developer and optionally contain further additives. Replenishment may be tailored to the developing apparatuses used, daily plate throughputs, image areas, etc. and are in general from 1 to 50 ml per square meter of plate precursor. Addition of replenisher can be regulated, for example, by measuring the conductivity of the developer as described in EP-A 0 556 690.

Off-press development is preferably carried out at temperatures of from 20 to 40° C. in automated processing units as customary in the art.

To increase the resistance of the finished printing plate and hence to extend the run length, the layer can be briefly heated to elevated temperatures (“baking”). The plate can be dried before baking or is dried during the baking process itself. During the baking step, the plate can be heated at a temperature which is higher than the glass transition temperature of the thermoplastic particles, e.g. between 100° C. and 230° C. for a period of 40 minutes to 5 minutes. A preferred baking temperature is above 60° C. For example, the exposed and developed plates can be baked at a temperature of 230° C. for 5 minutes, at a temperature of 150° C. for 10 minutes or at a temperature of 120° C. for 30 minutes. Baking can be done in conventional hot air ovens or by irradiation with lamps emitting in the infrared or ultraviolet spectrum. As a result of this baking step, the resistance of the printing plate to plate cleaners, correction agents and UV-curable printing inks increases. A baking process as disclosed in EP 1 767 349 may also be applied in a preferred embodiment of the present invention.

The printing plate thus obtained can be used for conventional, so-called wet offset printing, in which ink and an aqueous dampening liquid is supplied to the plate. Another suitable printing method uses so-called single-fluid ink without a dampening liquid. Suitable single-fluid inks have been described in U.S. Pat. No. 4,045,232; U.S. Pat. No. 4,981,517 and U.S. Pat. No. 6,140,392. In a most preferred embodiment, the single-fluid ink comprises an ink phase, also called the hydrophobic or oleophilic phase, and a polyol phase as described in WO 00/32705.

In another embodiment of the invention the printing plate precursor, after exposure, is developed on-press, i.e. the exposed precursor is mounted on a printing press whereupon the non-image areas are removed by supplying ink and/or fountain to the mounted precursor. Preferably the development on-press is carried out as follows: while the print cylinder with the precursor mounted thereon rotates, the dampening form roller supplying the dampening liquid is dropped on the precursor, e.g. during 10 revolutions of the print cylinder, and subsequent thereto also the inking form rollers are dropped on the precursor. Generally, after about 100, more preferably after about 50 revolutions of the print cylinder, the first clear and useful prints are obtained, indicating the completion of the development. According to an alternative embodiment, the inking form rollers and the dampening form roller may be dropped simultaneously or the inking form rollers may be dropped first.

With regard to the dampening liquids useful in a preferred embodiment of the present invention, there is no particular limitation and commercially available dampening liquids, also known as fountain solutions, can be used in the recommended dilution. The dampening liquid may comprise isopropyl alcohol (IPA) or any known IPA-replacing compound.

Preferably, after the on-press development is completed, the ink is removed from the plate by printing with the inking form rollers disengaged, so called “sheeting off” of the ink. Alternatively, one may also stop the press and clean the plate manually with a plate cleaner. One may also make use of any possible “washing device” on the press that allows cleaning the plate and removing the ink from its image areas during operation, while the ink and dampening form rollers are disengaged.

In another preferred embodiment, development off-press with e.g. a developing solution, wherein the non-exposed areas of the image recording layer are partially removed, may be combined with a development on press, wherein a complete removal of the non-exposed is realised.

### EXAMPLES

### Materials

All materials used in the examples were readily available from standard sources such as Aldrich Chemical Co. (Belgium) and Acros (Belgium) unless otherwise specified.

In the following list, ingredients used in the examples are listed. Where appropriate, it is mentioned how the ingredient (as a solution, as a dispersion etc.) is used in the examples.
Chemfac PB-133, an alkyl ether phosphate surfactant from Chemax Inc.
SDS Ultra Pure, sodium dodecyl sulphate from Alkemi BV.
HEDP, an aqueous solution containing 6 wt. % 1-hydroxyethylidene-1,1-diphosphonic acid from Solutia.
Zonyl FS0100, an aqueous solution containing 5 wt. % of the fluorinated surfactant Zonyl FS0100 from Dupont.
Zonyl FSP, a solution of fluorinated surfactants in water/isopropanol (35 wt. % solids) from Dupont.
Pigment, an aqueous blue pigment dispersion from Cabot Corporation containing 5 wt. % of the modified Cu phthalocyanine pigment IJX883.
Binder, an aqueous solution containing 1.5 wt. % Aqualic AS58 from Nippon Shokubai.
Dye, an aqueous solution (ethanol/water 50/50) containing 1.0 wt. % of the following dye:

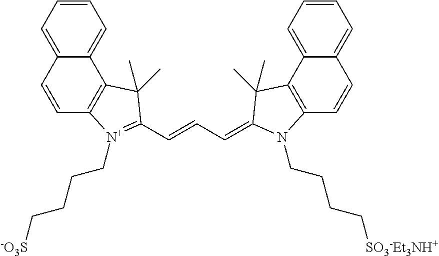

COMP IR-01, a 1 wt. % solution (Ethanol/water 50/50) of the following IR-dye:

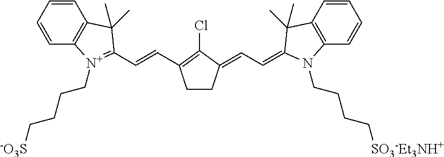

COMP IR-02, a 1 wt. % solution (Ethanol/water 50/50) of the following IR-dye:

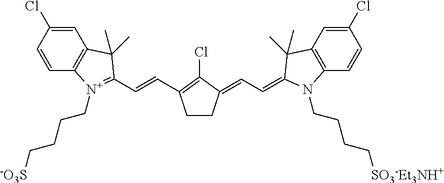

COMP IR-03, a 1 wt. % solution (Ethanol/water 50/50) of the following IR-dye:

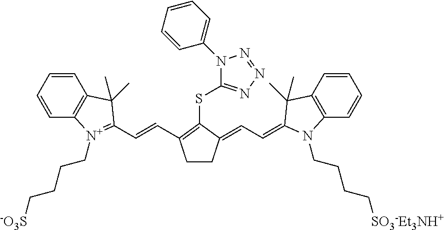

COMP IR-04, a 1 wt. % solution (Ethanol/water 50/50) of the following IR-dye:

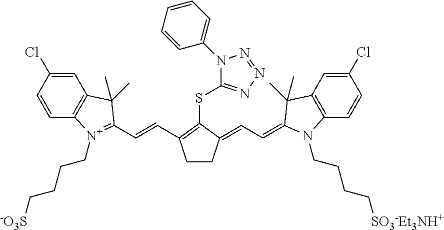

COMP IR-05, a 1 wt. % solution (Ethanol/water 50/50) of the following IR-dye:

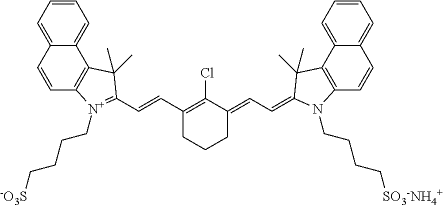

COMP IR-06, a 1 wt. % solution (ethanol/water 50/50) of the following IR-dye:

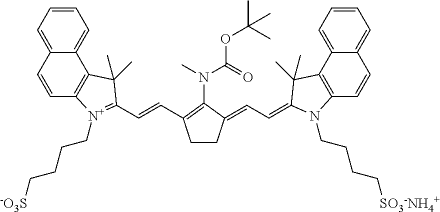

COMP IR-07, a 1 wt. % solution (ethanol/water 50/50) of the following IR-dye:

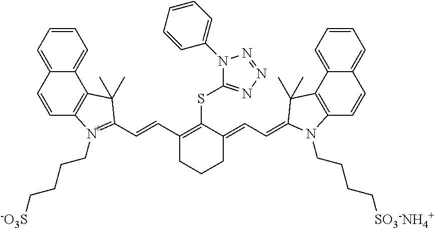

COMP IR-08, a 1 wt. % solution (ethanol/water 50/50) of the following IR-dye:

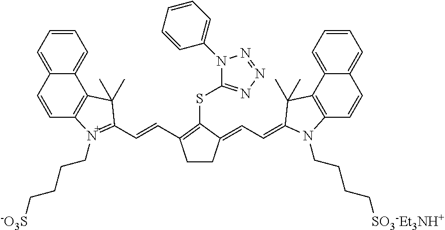

COMP IR-09, a 1 wt. % solution (ethanol/water 50/50) of the following IR-dye:

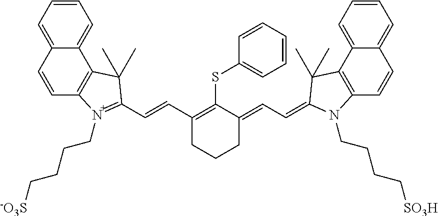

Avedex 37 LAC19, a potatoe dextrine from Avebe B.A. Adhesives.
Stabilizer, an aqueous solution containing 1% wt. of 5,6-isopropylidene-L-ascorbic acid from Chemsyntha N.V.
Dowfax 3B2, a surfactant from Dow Chemical.
Marlon, an aqueous solution of 148.0 g/l Marlon A365. Marlon 365, a mixture of alkylated sodium benzenesulphonic acids from SASOL Germany GmbH contains 65 wt. % solids.
Proxel Ultra5, an aqueous 5 wt. % solution of 1,2 benzisothiazole-3(2H)-one from Arch Biocides UK.
TD1000, a developer from Agfa Graphics NV.
RC795, a gum solution available from Agfa Graphics NV.

### Synthesis of the IR-Dyes

As mentioned in the description, the preparation of cyanine dyes is well known in the art. As an example the preparation methods are described below for the two inventive IR-dyes IR-05 and IR-07. The other IR-dyes used in the examples can be prepared in an analogue way. The reaction scheme to prepare IR-05 and IR-07 is shown below in scheme 1.

Under stirring a mixture of intermediate 1 (100 g, commercially available from Aurora) and butane sultone (142 g) in sulfolane (140 ml) is heated at 120-130° C. for 23 hours. After cooling to 55° C., acetone (700 ml) is added and intermediate 2 is allowed to crystallize. After filtration, the crude product is digested in acetone (450 ml), filtered and dried at 50° C. Intermediate 2 is obtained at a yield of 126 g (85%) as a light grey powder.

A mixture of intermediate 2 (130 g) and intermediate 3 (40 g, commercially available from Obiter) is suspended in ethanol (300 ml). Under stirring, a mixture of acetic acid anhydride (143 ml) and triethylamine (63.6 ml) is added over a 5 minute period (exothermic reaction). After reacting for 30 minutes at reflux, the reaction mixture is allowed to cool to room temperature. Ethyl acetate containing 2% water (2 l) is added and IR-05 crystallizes. After 2 hours, IR-05 is filtered, washed with ethyl acetate (3×200 ml) and dried under vacuum at room temperature. 154 g of IR-5 (yield is 93%) was obtained as a brown-green powder. IR-05 has an absorption maximum in Ethanol of 823 nm.

To prepare IR-07, to a suspension IR-05 (10.86 g) and N-phenyl mercaptotetrazole (1.78 g) in acetonitrile (50 ml) is added

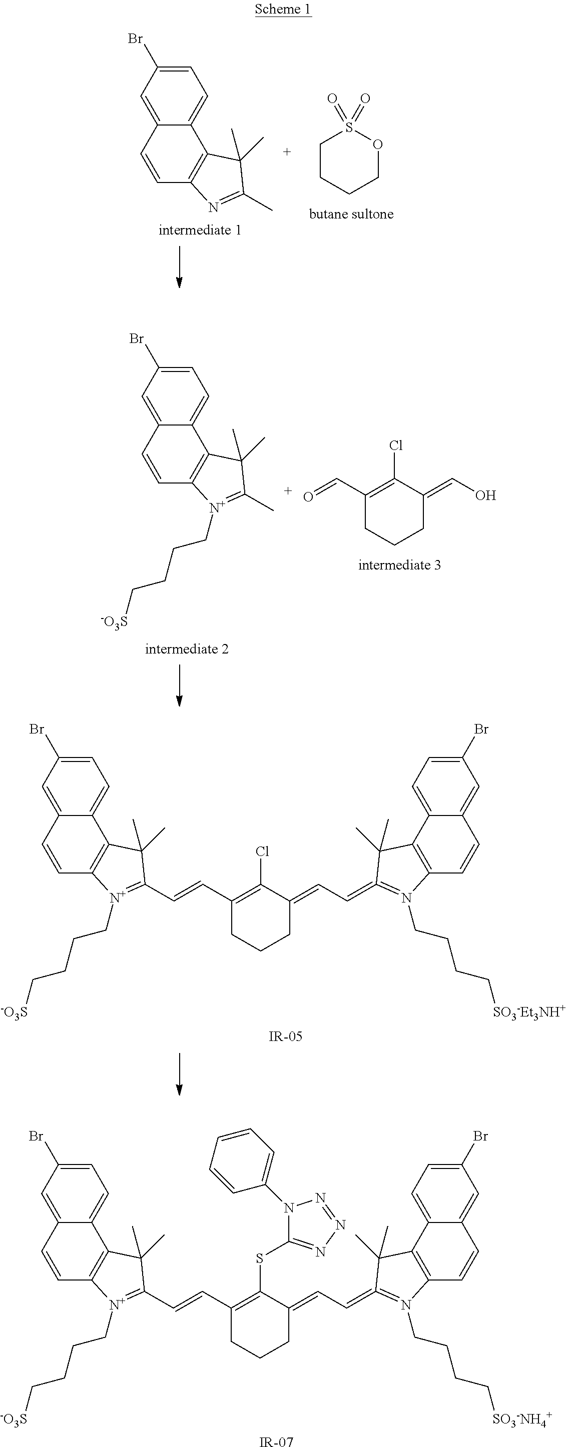

triethylamine (2.77 ml) under stirring at room temperature. After heating the reaction mixture at reflux for 1 hour, acetonitrile (50 ml) is added. After cooling to room temperature, IR-56 (10.82 g, yield 88%) is isolated by filtration and dried under vacuum at room temperature as a brown powder. IR-56 has an absorption maximum in methanol of 848 nm. To a solution of IR-56 (5.0 g) in methanol (100 ml) is added a solution of ammonium acetate (344 mg) in methanol (100 ml). After stirring for 2 hours at room temperature, IR-07 is filtered, washed with ethyl acetate (20 ml) and dried under vacuum at room temperature. 4.33 g of IR-07 was obtained (yield=92%) as a green powder. IR-07 has an absorption maximum in methanol of 849 nm.

### Example 1

### Aluminum substrate AS-01

A 0.30 mm thick aluminum foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a current density of about 100 A/dm² (charge density of about 800 C/dm²). Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm² (charge density of 330 C/dm²), then washed with demineralised water for 7 seconds and dried at 120° C. for 7 seconds.

The support thus obtained was characterised by a surface roughness Ra of 0.35-0.4 μm (measured with interferometer NT1100) and an anodic weight of about 4.0 g/m².

### Synthesis of the Latex LX-01

The polymer emulsion was prepared by a seeded emulsion polymerisation using styrene and acrylonitrile as monomers. All surfactant (4.5% towards the total monomer amount) was present in the reactor before any monomer was added. In a double-jacketed reactor of 2 liter, 10.35 g of Chemfac PB-133, 1.65 g of NaHCO₃ and 1482.1 g of demineralised water was added. The reactor was flushed with nitrogen and heated until 75° C. When the reactor content reached a temperature of 75° C., 1.5% of the monomers were added (i.e. a mixture of 2.29 g styrene and 1.16 g acrylonitrile). The monomers were emulsified during 15 minutes at 75° C. followed by the addition of 37.95 gram of a 2% solution of sodium persulfate in water. The reactor was subsequently heated to a temperature of 80° C. during 30 minutes. Then, the remaining monomer mixture (150.1 g of styrene and 76.5 g of acrylonitrile) was dosed to the reaction mixture during 180 minutes. Simultaneously with the monomer addition, an additional amount of an aqueous persulfate solution was added (37.95 g. of a 2% aqueous Na₂S₂O₈ solution). After the monomer addition was completed, the reactor was heated for 60 minutes at 80° C. To reduce the amount of residual monomer a vacuum distillation was performed at 80° C. during 1 hour. The reactor was subsequently cooled to room temperature, 100 ppm Proxel Ultra was added as biocide and the latex was filtered using coarse filter paper.

This resulted in a latex dispersion LX-01 with a solid content of 13.14% and a pH of 6.10. The average particle size was 29 nm as measured using PL-PSDA (Polymer Laboratories Particle Size Diameter Analyser). Measured with BI-90 this resulted in a mean particle size of 31 nm.

### Printing Plate Precursors PPP-01 to PPP-08

The coating solutions of the printing plate precursors PPP-01 to PPP-08 were prepared using the materials as described above. The coating solutions were coated on the aluminum substrate AS-01 with a coating knife at a wet thickness of 30 μm. After drying at 60° C., the printing plate precursors PPP-01 to PPP-08, of which the dry coating weight of the different components is given in Table 1, were obtained. The dry coating weights used in Table 1 refer to the weight of the ingredients as such and not to the weight of the solutions or dispersions of the ingredients, i.e. those mentioned in the material list above, used to prepare the precursors.

TABLE 1

| Ingredients | | | | | | |
|---|---|---|---|---|---|---|
| (g/m2) | PPP-01 | PPP-02 | PPP-03 | PPP-04 | PPP-05 | PPP-06 |
| Latex LX-01 | 0.3327 | 0.3327 | 0.3327 | 0.3327 | 0.3327 | 0.3327 |
| COMP IR-01 | 0.0531 | — | — | — | — | — |
| COMP IR-02 | — | 0.0575 | — | — | — | — |
| IR-01 | — | — | 0.0633 | — | — | — |
| IR-02 | — | — | — | 0.0695 | — | — |
| COMP IR-03 | — | — | — | — | 0.0623 | — |
| COMP IR-04 | — | — | — | — | — | 0.0677 |
| Pigment | 0.0200 | 0.0200 | 0.0200 | 0.0200 | 0.0200 | 0.0200 |
| Dye | 0.0090 | 0.0090 | 0.0090 | 0.0090 | 0.0090 | 0.0090 |
| Binder | 0.0197 | 0.0197 | 0.0197 | 0.0197 | 0.0197 | 0.0197 |
| HEDP | 0.0150 | 0.0150 | 0.0150 | 0.0150 | 0.0150 | 0.0150 |
| Surfactant | 0.0050 | 0.0050 | 0.0050 | 0.0050 | 0.0050 | 0.0050 |
| Total | 0.4545 | 0.4589 | 0.4647 | 0.4709 | 0.4582 | 0.4691 |

| Ingredients | | |
|---|---|---|
| (g/m2) | PPP-07 | PPP-08 |
| Latex LX-01 | 0.3327 | 0.3327 |
| IR-03 | 0.0726 | — |
| IR-04 | — | 0.0787 |
| Pigment | 0.0200 | 0.0200 |
| Dye | 0.0090 | 0.0090 |
| Binder | 0.0197 | 0.0197 |
| HEDP | 0.0150 | 0.0150 |
| Surfactant | 0.0050 | 0.0050 |
| Total | 0.4710 | 0.4801 |

### Exposure, Development and Printing of PPP-01 to PPP-08

The printing plate precursors PPP-01 to PPP-08 were exposed on a Creo TrendSetter 3244 (40W head) IR-laser platesetter at 210-180-150-120-90 mJ/cm² at 150 rotations per minute (rpm) with a 200 line per inch (lpi) screen and an addressability of 2400 dpi.

After exposure the printing plate precursors were developed in an Ozazol VA88 processor (from Agfa Graphics NV) with TD1000 developer (from Agfa Graphics NV) at 22° C. in the developer section and a 1:1 diluted RC795 gum solution (from Agfa Graphics NV) at 22° C. in the gumming section. The development speed amounted to 1.2 m/min.

After development and gumming the printing plates were mounted on a Heidelberg GTO52 printing press equipped with a Kompac III dampening system. A compressible blanket was used and printing was done with the fountain solution 4% Agfa Prima FS4014 (trademark of Agfa Graphics) and K+E 800 black ink (trademark of K&E). The following start-up procedure was used: first 5 revolutions with the dampening form rollers engaged, then 5 revolutions with both the dampening and ink form rollers engaged, then printing started. 1,000 prints were made on 80 g/m² offset paper.

Evaluation of printing plate precursors PPP-01 to PPP-08

The printing plate precursors were evaluated through the following characteristics:
Clean-out (plate): The clean-out of the plate is assessed by a colourimetric measurement of both the non-image areas of each printing plate after development (TD1000) and the according blank substrate used (AS-01). Based upon these CIELab value measurements the according ΔE value is calculated.
Clean-out (printed sheet): After 750 prints, the paper sheet size is shortened and printing is continued for another 250 prints. After 1 000 prints, a few more prints are generated on the normal paper size. If any staining should occur, this will result in an accumulation of ink on the blanket, while printing is performed with the shortened paper size. This accumulated ink will then be transferred to the paper when the normal paper size is used again, after 1 000 prints. This method allows for a very precise evaluation of the stain level. A value of 5.0 indicates that no stain is observed after 1 000 prints. A value of 4.0 would be barely acceptable. A value of 3.0 would be totally unacceptable for high quality print jobs.
Sensitivity 1: the lowest exposure energy density (mJ/cm2) at which 2% dots are perfectly visible (by a 5× magnifying glass) on the one-thousandth (1000th) print on paper.
Sensitivity 2: the interpolated energy density value (mJ/cm2) where the surface coverage (calculated from the measured optical density of the one-thousandth print on paper) of a B-25 2% dot patch equals 55%. A B-25 2% dot patch consists of 2% ABS (200 lpi, 2400 dpi) dots, but the total surface coverage of these dots is 25%. ABS dots are generated with the Agfa Balanced Screening methodology.

The optical densities referred to above are all measured with a GretagMacbeth densitometer type D19C. The CIELab value measurements were performed using a Gretag SP50 spectrophotometer from GretagMacBeth.

The results of the evaluation are given in Table 2.

TABLE 2

| | | | PPP- | PPP- | | |
|---|---|---|---|---|---|---|
| | PPP-01 | PPP-02 | 03 | 04 | PPP-05 | PPP-06 |
| Characteristics | (COMP) | (COMP) | (INV) | (INV) | (COMP) | (COMP) |
| Substituent | H | Cl | Br | I | H | Cl |
| Clean out | 20.0 | 10.0 | 6.7 | 4.9 | 14.5 | 12.3 |
| (plate) | | | | | | |
| Clean out | * | * | 4.0 | 4.0 | * | * |
| (printed sheet) | | | | | | |
| Sensitivity 1 | ** | ** | 120 | 120 | ** | ** |
| Sensitivity 2 | ** | ** | 97 | 79 | ** | ** |

| | PPP-07 | PPP-08 |
|---|---|---|
| Characteristics | (INV) | (INV) |
| Substituent | Br | I |
| Clean out | 0.5 | 3.8 |
| (plate) | | |
| Clean out | 4.5 | 4.0 |
| (printed sheet) | | |
| Sensitivity 1 | 120 | 120 |
| Sensitivity 2 | 122 | 119 |

* since there is still toning on printed sheet 750, this special cleanout test (shortened paper) could not be performed.
** could not be assessed due to heavy toning on printed sheet 1000.

It is clear from Table 2 that the inventive examples PPP-03, PPP-04, PPP-07 and PPP-08 are characterized by a substantially improved clean-out, both on plate and on paper, compared with the comparative examples. Due to their better clean-out behaviour, the inventive examples are also characterized by a high sensitivity.

### Example 2

### Aluminum Substrate AS-02

A 0.3 mm thick aluminum foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO₄²⁻ ions and 5 g/l Al³⁺ ions at a temperature of 37° C. and a current density of about 100 A/dm² (charge density of about 800 C/dm²). Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm² (charge density of 330 C/dm²), then washed with demineralised water for 7 seconds and post-treated for 4 seconds (by spray) with a solution containing 2.2 g/l PVPA at 70° C., rinsed with demineralised water for 3.5 seconds and dried at 120° C. for 7 seconds.

The support thus obtained is characterised by a surface roughness Ra of 0.35-0.4 μm (measured with interferometer NT1100) and an anodic weight of about 4.0 g/m².

### Synthesis of the Latex LX-02

The polymer emulsion is prepared by a seeded emulsion polymerisation using styrene and acrylonitrile as monomers. The total amount of surfactant (2.5% towards the total monomer amount) is present in the reactor before the monomer addition is started. In a reactor of 100 1, 0.4 kg of Sodium dodecyl sulfate (SDS Ultra Pure) and 48.9 kg of demineralised water was added. The reactor was flushed with nitrogen and heated until 75° C. When the reactor content reached a temperature of 75° C., 119 g of acrylontrile and 233 g of styrene was added to the reactor. The flask used for the monomer addition was rinsed with 1 l of demineralised water and this rinse water was also added to the reactor. The monomer was emulsified in the reactor during 15 minutes. Subsequently 2640 g of a 2% solution of sodium persulfate in water was added. After 5 minutes the reactor was heated form 75° C. to 80° C. during 30 minutes. Then, the monomer mixture (5.28 kg of styrene and 10.37 kg of acrylonitrile) was dosed during 180 minutes at 80° C. Simultaneously with the monomer addition an additional aqueous sodium persulfate solution was added (2640 g of a 2% aqueous Na₂S₂O₈ solution). Upon finishing the dosing, both the monomer flask and the initiator flask were rinsed with demineralised water, respectively with 1 l and 0.5 l. Both rinse waters were added to the reactor. Then, the reactor was heated for 60 minutes at 80° C. To reduce the amount of residual monomer a redox-initiation system is added (69 g sodium formaldehyde sulfoxylate dihydrate (SFS) dissolved in 5224 g water and 114 g of a 70 wt % tert.butyl hydroperoxide (TBHP) diluted with 886 gof water. The aqueous solutions of SFS and TBHP were added separately during 80 minutes. The reaction was then heated for another 10 minutes and subsequently cooled to room temperature. 100 ppm of Proxel Ultra (152 gram of a 5.25% solution) was added as biocide and the latex was filtered using a coarse 5 μm Pall filter.

This resulted in a latex dispersion LX-02 with a solid content of 20.7% and a pH of 2.6. The average particle size was 34 nm as measured using PL-PSDA (Polymer Laboratories Particle Size Diameter Analyser). Measured with BI-90 this resulted in a mean particle size of 40 nm.

### Printing Plate Precursors PPP-09 to PPP-12

The coating solutions of the printing plate precursors PPP-09 to PPP-12 were prepared using the materials as described above. The coating solutions were coated on the aluminum substrate AS-02 with a coating knife at a wet thickness of 30 μm. After drying at 60° C., the printing plate precursors PPP-09 to PPP-12, of which the dry coating weight of the different components is given in Table 3, were obtained. The dry coating weights used in Table 3 refer to the weight of the ingredients as such and not to the weight of the solutions or dispersions of the ingredients, i.e. those mentioned in the material list above, used to prepare the precursors.

TABLE 3

| Ingredients | | | | |
|---|---|---|---|---|
| (g/m2) | PPP-09 | PPP-10 | PPP-11 | PPP-12 |
| Latex LX-02 | 0.4000 | 0.4000 | 0.3500 | 0.3500 |
| COMP IR-05 | 0.0530 | — | — | — |
| IR-05 | — | 0.0680 | — | — |
| COMP IR-06 | — | — | 0.0610 | — |
| IR-06 | — | — | — | 0.0710 |
| Dye | 0.0010 | 0.0010 | — | — |
| Binder | 0.0320 | 0.0320 | 0.0480 | 0.0480 |
| HEDP | 0.0250 | 0.0250 | 0.0120 | 0.0120 |
| Stabilizer | — | — | 0.0100 | 0.0100 |
| Surfactant | 0.0050 | 0.0050 | 0.0050 | 0.0050 |
| Total | 0.5130 | 0.5310 | 0.4860 | 0.4960 |

The resulting printing plate precursors PPP-09 to PPP-12 were partly stored during 7 days in a warm and humid cabinet (35° C./80% R.H.). This resulted in so-called “aged” printing plate precursors (vs. the original “fresh” printing plate precursors).

### Exposure, Development and Printing of PPP-09 to PPP-12.

Both the “fresh” and the “aged” printing plate precursors were exposed on a Creo TrendSetter 3244 (40W head) IR-laser platesetter at 210-180-150-120-90 mJ/cm² at 150 rotations per minute (rpm) with a 200 line per inch (lpi) screen and an addressability of 2400 dpi.

The exposed “fresh” and “aged” printing plate precursors PPP-11 and PPP-12 were directly mounted on a Heidelberg GT052 printing press equipped with a Kompac III dampening system and this without any processing or pre-treatment. A compressible blanket was used and printing was done with the fountain solution 4% Emerald Premium 3520 (trademark of Anchor) and K+E 800 black ink (trademark of K&E). The following start-up procedure was used: first 5 revolutions with the dampening form rollers engaged, then 5 revolutions with both the dampening and ink form rollers engaged, then printing started. 1000 prints were made on 80 g/m² offset paper.

The exposed “fresh” and “aged” printing plate precursors PPP-09 and PPP-10 were developed in a clean-out unit (COU 80, trademark of Agfa Graphics NV) filled with a gum solution and operating at a throughput speed of 1.1 m/min. The composition of the gum solution used (at 22° C.) is given in Table 4.

TABLE 4

| Ingredients | | |
|---|---|---|
| Demineralised water | 750 | ml |
| Avedex 37 LAC19 | 38.0 | g |
| KH2PO4 | 27.2 | g |
| KOH (50 wt. %) | 7.95 | ml |
| Dowfax 3B2 | 19.57 | ml |
| Marlon | 5.0 | g |
| Proxel Utra5 | 4.85 | ml |
| Zonyl FSP | 0.5 | g |
| Water | Until 1000 | ml |

| | |
|---|---|
| pH | 6.8-7.2 |

After development the according printing plates were mounted on the press and printing started as described for printing precursors PPP-11 and PPP-12.

### Evaluation of Printing Plate Precursors PPP-09 to PPP-12

All fresh printing plates cleaned out well and delivered toning-free prints from virtually the first printed sheet onwards, while the aged plates all showed initial clean-out problems.

The printing plate precursors are evaluated through the following characteristics:
Colour switch efficiency: the earliest exposure density (in mJ/cm²) at which the colour switch affected by the present thermochromic IR-dye in the imaged parts of the fresh printing plate precursor becomes visible.
Clean-out after ageing (printed sheet): both printed sheet 50 and printed sheet 250 were evaluated according to the following qualitative scale:
   5=D (non-image areas) lower than or equal than 0.025
   4=D (non-image areas) higher than 0.025 but lower than or equal to 0.08
   3=D (non-image areas) higher than 0.08 but lower than or equal to 0.15
   2=D (non-image areas) higher than 0.15 but lower than or equal to 0.35
   1=D (non-image areas) higher than 0.35 but lower than or equal to 1.2
   0=“black page” or in other words, D (non-image areas) higher than 1.2
Sensitivity 1: Plate sensitivity (2% dot) (mJ/cm²): the lowest exposure energy density at which 2% dots are perfectly visible (by a 5× magnifying glass) on the one-thousandth (1000^{th}) print on paper.

The optical densities (D) referred to above are all measured with a Gretag Macbeth densitometer type D19C.

The results are given in Table 5.

TABLE 5

| | PPP-09 | PPP-10 | PPP-11 | PPP-12 |
|---|---|---|---|---|
| | (COMP) | (INV) | (COMP) | (INV) |
| Substituent | H | Br | H | Br |
| Colour Switch Efficiency | * | * | 120 | 90 |
| Clean-out after ageing | 1.5 | 5 | 0 | 3 |
| (printed sheet 50) | | | | |
| Clean-out after ageing | 2 | 5 | 1 | 3.5 |
| (printed sheet 250) | | | | |
| Sensitivity 1 | 150 | 120 | 150 | 120 |

* not relevant

It is clear from Table 5 that the inventive precursor PPP-10, compared to the comparative precursor PPP-09, is characterized by a better clean-out after ageing (higher number is an improved clean-out) and a higher sensitivity (lower number is a higher sensitivity). It is also clear from Table 5 that the inventive precursor PPP-12, compared to the comparative precursor PPP-11, is characterized by an improved colour switch efficiency, a better clean-out and a higher sensitivity.

### Example 3

### Printing Plate Precursors PPP-13 to PPP-16

The coating solutions of the printing plate precursors PPP-13 to PPP-16 were prepared using the materials as described above. The coating solutions were coated on the aluminum substrate AS-02 with a coating knife at a wet thickness of 30 μm. After drying at 60° C., the printing plate precursors PPP-13 to PPP-16, of which the dry coating weight of the different components is given in Table 6, were obtained. The dry coating weights used in Table 6 refer to the weight of the ingredients as such and not to the weight of the solutions or dispersions of the ingredients, i.e. those mentioned in the material list above, used to prepare the precursors.

TABLE 6

| Ingredients | | | | |
|---|---|---|---|---|
| (g/m²) | PPP-13 | PPP-14 | PPP-15 | PPP-16 |
| Latex LX-02 | 0.4400 | 0.4400 | 0.4400 | 0.4400 |
| COMP IR-07 | 0.0642 | — | — | — |
| IR-07 | — | 0.0745 | — | — |
| COMP IR-08 | — | — | 0.0688 | — |
| IR-08 | — | — | — | 0.0791 |
| Pigment | 0.0200 | 0.0200 | 0.0200 | 0.0200 |
| Dye | 0.0090 | 0.0090 | 0.0090 | 0.0090 |
| Binder | 0.0260 | 0.0260 | 0.0260 | 0.0260 |
| HEDP | 0.0150 | 0.0150 | 0.0150 | 0.0150 |
| Surfactant | 0.0050 | 0.0050 | 0.0050 | 0.0050 |
| Total | 0.5792 | 0.5895 | 0.5838 | 0.5941 |

### Exposure, Development and Printing of PPP-13 to PPP-16

The printing plate precursors were exposed, developed, gummed and printed as outlined in Example 1.

### Evaluation of Printing Plate Precursors PPP-13 to PPP-16

All fresh printing plates cleaned out well and delivered toning-free prints from virtually the first printed sheet onwards.

The printing plate precursors are evaluated through the following characteristic:
Sensitivity 2: the interpolated energy density value (mJ/cm²) where the surface coverage (calculated from the measured optical density of the one-thousandth print on paper) of a B-25 2% dot patch equals 55%. A B-25 2% dot patch consists of 2% ABS (200 lpi, 2400 dpi) dots, but the total surface coverage of these dots is 25%. ABS dots are generated with the Agfa Balanced Screening methodology.

The optical densities referred to above are all measured with a Gretag Macbeth densitometer type D19C.

The results are given in Table 7.

TABLE 7

| | PPP-13 | PPP-14 | PPP-15 | PPP-16 |
|---|---|---|---|---|
| | (COMP) | (INV) | (COMP) | (INV) |
| Substituent | H | Br | H | Br |
| Sensitivity 2 | 205 | 117 | 160 | 117 |

It is clear from Table 7 that the inventive precursors PPP-14 and 16, compared to PPP-13 and PPP-15, are characterized by an increased sensitivity.

### Example 4

### Printing Plate Precursors PPP-17 to PPP-19

The coating solutions of the printing plate precursors PPP-17 to PPP-19 were prepared using the materials as described above. The coating solutions were coated on the aluminum substrate AS-01 with a coating knife at a wet thickness of 30 μm. After drying at 60° C., the printing plate precursors PPP-17 to PPP-19, of which dry coating weight of the different components is given in Table 8, were obtained. The dry coating weights used in Table 8 refer to the weight of the ingredients as such and not to the weight of the solutions or dispersions of the ingredients, i.e. those mentioned in the material list above, used to prepare the precursors.

TABLE 8

| Ingredients | | | |
|---|---|---|---|
| (g/m²) | PPP-17 | PPP-18 | PPP-19 |
| Latex LX-01 | 0.4658 | 0.4658 | 0.4658 |
| COMP IR-09 | 0.0587 | — | — |
| IR-25 | — | 0.0690 | — |
| IR-68 | — | — | 0.0653 |
| Pigment | 0.0200 | 0.0200 | 0.0200 |
| Dye | 0.0090 | 0.0090 | 0.0090 |
| Binder | 0.0236 | 0.0236 | 0.0236 |
| HEDP | 0.0150 | 0.0150 | 0.0150 |
| Surfactant | 0.0050 | 0.0050 | 0.0050 |
| Total | 0.5971 | 0.6074 | 0.6037 |

The resulting printing plate precursors PPP-17 to PPP-19 were partly stored during 7 days in a warm and humid cabinet (35° C./80% R.H.). This resulted in so-called “aged” printing plate precursors (vs. the original “fresh” printing plate precursors).

### Exposure, Development and Printing of PPP-17 to PPP-19

The printing plate precursors were exposed, developed, gummed and printed as outlined in Example 1.

### Evaluation of Printing Plate Precursors PPP-17 to PPP-19

Both the “fresh” and the “aged” printing plate precursors are evaluated through the following characteristics:
Clean-out (plate): The clean-out of the plate was assessed according to the following qualitative scale:
   5=“no stain” (unwanted remaining coating on the plate in the non-image areas) or in other words, CIELab ΔE values (non-image areas) lower than or equal than 0.5*
   4=ΔE (non-image areas) higher than 0.5 but lower than or equal to 1.2*
   3=ΔE (non-image areas) higher than 1.2 but lower than or equal to 3.5*
   2=ΔE (non-image areas) higher than 3.5 but lower than or equal to 8*
   1=ΔE (non-image areas) higher than 8.0 but lower than or equal to 15*
   0=ΔE (non-image areas) higher than 15*

The CIELab ΔE values referred to above are all measured with a GretagMacBeth SPM50 spectrophotometer versus a blanco aluminium substrate (L=79.12, a=−0.36, b=−1.51).
Clean-out (printed sheet): the clean-out of the plate was assessed by counting the number of printed sheets required to get to a point where no visible toning is present on the printed sheet anymore.
Sensitivity 1: plate sensitivity (2% dot) (mJ/cm²)=the lowest exposure energy density at which 2% dots are perfectly visible (by a 5× magnifying glass) on the one-thousandth (1000^{th}) print on paper.
Sensitivity 2: plate sensitivity (B-25 2%) (mJ/cm²)=the interpolated energy density value where the surface coverage (calculated from the measured optical density of the one-thousandth print on paper) of a B-25 2% dot patch equals 55%. A B-25 2% dot patch consists of 2% ABS (200 lpi, 2400 dpi) dots, but the total surface coverage of these dots is 25%. ABS dots are generated with the Agfa Balanced Screening methodology.

The optical densities referred to above are all measured with a GretagMacbeth densitometer type D19C.

The results are given in Table 9.

TABLE 9

| | PPP-17 | PPP-18 | PPP-19 |
|---|---|---|---|
| | (COMP) | (INV) | (INV) |
| Substituent | H | Br | Br |
| Clean-out (plate) (“fresh” plate) | 3.5 | 4.5 | 4 |
| Clean-out (printed sheet) | >1000 | 25 | 75 |
| (“fresh”plate) | | | |
| Sensitivity 1 (“fresh plate”) | * | 120 | 90 |
| Sensitivity 2 (“fresh plate”) | * | 114 | 97 |
| Clean-out (plate) (“aged plate”) | 1.5 | 4 | 4 |

* could not be assessed due to heavy toning on printed sheet 1000.

It is clear from Table 9 that the inventive precursors PPP-18 and 19 are characterized by an improved clean-out, especially after ageing, and a high sensitivity.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-17. (canceled)

18. A lithographic printing plate precursor comprising:
a coating provided on a support having a hydrophilic surface, the coating including:
thermoplastic polymer particles; and
an infrared radiation absorbing dye; wherein
the infrared radiation absorbing dye contains a substituent selected from bromo and iodo.

19. The lithographic printing plate precursor according to claim 18, wherein the infrared radiation absorbing dye contains two substituents selected from bromo and iodo.

20. The lithographic printing plate precursor according to claim 18, wherein the infrared radiation absorbing dye is a cyanine dye having a structure according to Formula I: 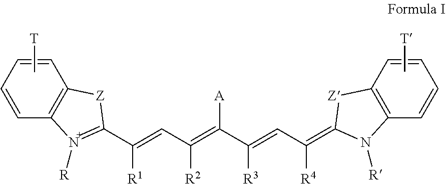
wherein
Z and Z′ represent —S—, —CR^{a}R^{b}—, or —CH═CH—, wherein R^{a} and R^{b} represent an alkyl, aralkyl, or aryl group;
A represents hydrogen, an optionally substitued alkyl, aralkyl, or aryl group, halogen, —OR^{c}, —SR^{d}, —SO₂R^{e}, —NR^{f}R^{g}, —NR^{h}(SO₂Rⁱ), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ¹Rⁱ² wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
R¹, R², R³, and R⁴ represent hydrogen or an optionally substituted alkyl group;
R, R′, and R¹ to R⁴ may form a ring; and
T and T′ independently represent hydrogen, halogen, alkyl, alkoxy, cyano, —CO₂R^{k}, —CONR^{l}R^{m}, —SO₂Rⁿ, —SO₂NR^{o}R^{p}, or an optionally substituted annulated benzo ring; wherein
R^{l}, R^{m} represent hydrogen or an optionally substituted alkyl or aryl group;
Rⁿ represents an optionally substituted alkyl or aryl group; and
R^{o} and R^{p} represent hydrogen or an optionally substituted alkyl or aryl group.

21. The lithographic printing plate precursor according to claim 18, wherein the infrared radiation absorbing dye is a cyanine dye having a structure according to Formula II: 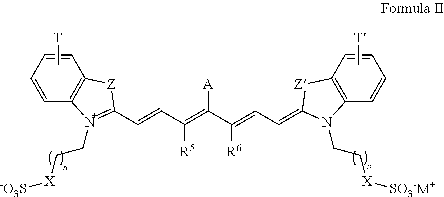
wherein
Z and Z′ represent —S—, —CR^{a}R^{b}—, or —CH═CH—, wherein R^{a} and R^{b} represent an alkyl, aralkyl, or aryl group;
A represents hydrogen, an optionally substitued alkyl, aralkyl, or aryl group, halogen, —OR^{c}, —SR^{d}, —SO₂R^{e}, —NR^{f}R^{g}, —NR^{h}(SO₂R¹), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ¹Rⁱ² wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
T and T′ independently represent hydrogen, halogen, alkyl, alkoxy, cyano, —CO₂R^{k}, —CONR^{l}R^{m}, —SO₂Rⁿ, —SO₂NR^{o}R^{p}, or an optionally substituted annulated benzo ring; wherein
R^{l}, R^{m} represent hydrogen or an optionally substituted alkyl or aryl group;
Rⁿ represents an optionally substituted alkyl or aryl group; and
R^{o} and R^{p} represent hydrogen or an optionally substituted alkyl or aryl group;
R⁵ and R⁶ represent the necessary atoms to form a ring;
n represents an integer ranging from 0 to 3;
X represents —CH₂—, —O—, or —S—; and
M⁺ represents a counterion to balance the charge.

22. The lithographic printing plate precursor according to claim 18, wherein the infrared radiation absorbing dye is a cyanine dye having a structure according to Formula III: 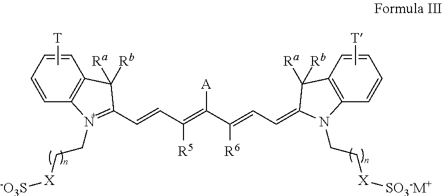
wherein
A represents hydrogen, an optionally substitued alkyl, aralkyl, or aryl group, halogen, —OR^{c}, —SR^{d}, —SO₂R^{e}, —NR^{f}R^{g}, —NR^{h}(SO₂Rⁱ), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ²Rⁱ² wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
T and T′ independently represent hydrogen, halogen, alkyl, alkoxy, cyano, —CO₂R^{k}, —CONR^{l}R^{m}, —SO₂Rⁿ, —SO₂NR^{o}R^{p}, or an optionally substituted annulated benzo ring; wherein
R^{l}, R^{m} represent hydrogen or an optionally substituted alkyl or aryl group;
Rⁿ represents an optionally substituted alkyl or aryl group; and
R^{o} and R^{p} represent hydrogen or an optionally substituted alkyl or aryl group;
R^{a} and R^{b} represent an alkyl, aralkyl, or aryl group;
R⁵ and R⁶ represent the necessary atoms to form a ring;
n represents an integer ranging from 0 to 3;
X represents —CH₂—, —O—, or —S—; and
M⁺ represents a counterion to balance the charge.

23. The lithographic printing plate precursor according claim 18, wherein the infrared radiation absorbing dye is a cyanine dye having a structure according to Formula IV: 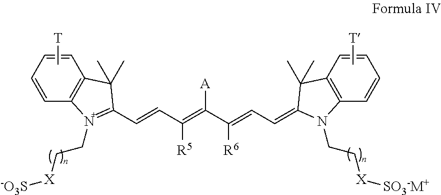
wherein
A represents hydrogen, an optionally substitued alkyl, aralkyl, or aryl group, halogen, —OR^{c}, —SR^{d}, —SO₂R^{e}, —NR^{f}R^{g}, —NR^{j}(SO₂Rⁱ), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ¹Rⁱ², wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
T and T′ independently represent hydrogen, halogen, alkyl, alkoxy, cyano, —CO₂R^{k}, —CONR^{l}R^{m}, —SO₂Rⁿ, —SO₂NR^{o}R^{p} or an optionally substituted annulated benzo ring; wherein
R^{l}, R^{m} represent hydrogen or an optionally substituted alkyl or aryl group;
Rⁿ represents an optionally substituted alkyl or aryl group; and
R^{o} and R^{p} represent hydrogen or an optionally substituted alkyl or aryl group;
R⁵ and R⁶ represent the necessary atoms to form a ring;
n represents an integer ranging from 0 to 3;
X represents —CH₂—, —O—, or —S—; and
M⁺ represents a counterion to balance the charge.

24. The lithographic printing plate precursor according to claim 18, wherein the infrared radiation absorbing dye is a cyanine dye having a structure according to Formula V: 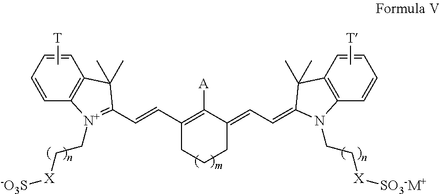
wherein
A represents hydrogen, an optionally substitued alkyl, aralkyl, or aryl group, halogen, —OR^{c}, —SR^{d}, —SO₂R^{e}, —NR^{f}R^{g}, —NR^{h}(SO₂Rⁱ), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ¹Rⁱ² wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
T and T′ independently represent hydrogen, halogen, alkyl, alkoxy, cyano, —CO₂R^{k}, —CONR^{l}R^{m}, —SO₂Rⁿ, —SO₂NR^{o}R^{p}, or an optionally substituted annulated benzo ring; wherein
R^{l}, R^{m} represent hydrogen or an optionally substituted alkyl or aryl group;
Rⁿ represents an optionally substituted alkyl or aryl group; and
R^{o} and R^{p} represent hydrogen or an optionally substituted alkyl or aryl group;
n represents an integer ranging from 0 to 3;
X represents —CH₂—, —O—, or —S—; and
M⁺ represents a counterion to balance the charge.

25. The lithographic printing plate precursor according to claim 18, wherein the infrared radiation absorbing dye is a cyanine dye having a structure according to Formula VI: 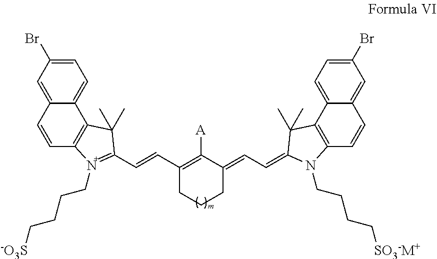
wherein
A represents hydrogen, an optionally substitued alkyl, aralkyl, or aryl group, halogen, —OR^{S}, —SR^{d}, —SO₂R^{e}, —NR^{f}R^{g}, —NR^{h}(SO₂Rⁱ), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ¹Rⁱ² wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
m represents 0 or 1; and
M⁺ represents a counterion to balance the charge.

26. The lithographic printing plate precursor according to claim 18, wherein the infrared radiation absorbing dye is a cyanine dye having a structure according to Formula VII: 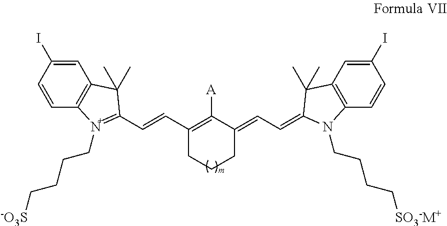
wherein
A represents hydrogen, an optionally substitued alkyl, aralkyl, or aryl group, halogen, —OR^{c}, —SR^{d}, —SO₂R^{e}, —NR^{f}R^{g}, —NR^{h}(SO₂Rⁱ), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ¹Rⁱ², wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
m represents 0 or 1; and
M⁺ represents a counterion to balance the charge.

27. The lithographic printing plate precursor according to claim 18, wherein the infrared radiation absorbing dye is a cyanine dye having a structure according to Formula VIII: 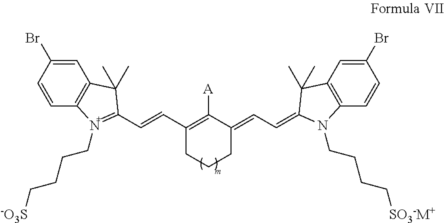
wherein
A represents hydrogen, an optionally substitued alkyl, aralkyl, or aryl group, halogen, —OR^{S}, —SR^{d}, —SO₂R^{e}, —NR^{f}R^{g}, —NR^{h}(SO₂Rⁱ), or —NR^{j}(CO₂R^{k}); wherein
R^{c} represents an optionally substituted aryl group;
R^{d} represents an optionally substituted alkyl, aralkyl, aryl, or heteroaryl group;
R^{e} represents an optionally substituted alkyl, aryl, or heteroaryl group;
R^{f} represents an optionally substituted alkyl, aralkyl, or aryl group;
R^{g} represents an optionally substituted aryl group;
R^{h} represents an optionally substituted alkyl or aryl group;
Rⁱ represents an optionally substituted alkyl or aryl group or —NRⁱ¹Rⁱ² wherein Rⁱ¹ and Rⁱ² represent hydrogen or an optionally substituted alkyl or aryl group;
R^{j} represents an optionally substituted alkyl or aryl group; and
R^{k}, R, and R′ represent an optionally substituted alkyl group;
m represents 0 or 1; and
M⁺ represents a counterion to balance the charge.

28. The lithographic printing plate precursor according to claim 20, wherein A is selected from: 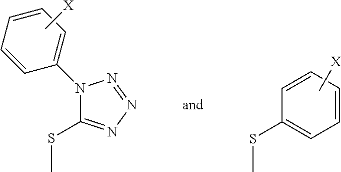
wherein X is an optional substituent.

29. The lithographic printing plate precursor according to claim 22, wherein A is selected from: 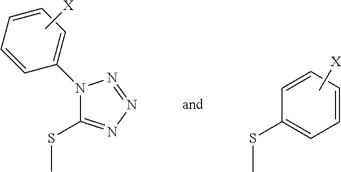
wherein X is an optional substituent.

30. The lithographic printing plate precursor according to claim 24, wherein A is selected from: 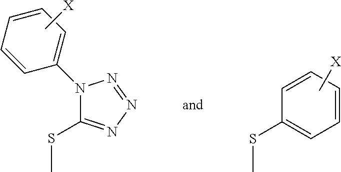
wherein X is an optional substituent.

31. The lithographic printing plate precursor according to claim 26, wherein A is selected from: 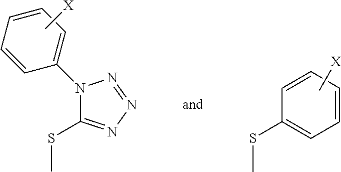
wherein X is an optional substituent.

32. The lithographic printing plate precursor according to claim 27, wherein A is selected from: 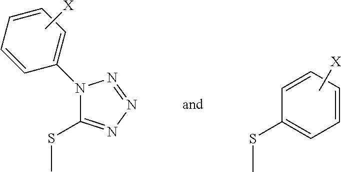
wherein X is an optional substituent.

33. The lithographic printing plate precursor according to claim 20, wherein A is selected from —NR^{h}(SO₂Rⁱ) and —NR^{j}(CO₂R^{k}), wherein R^{h}, Rⁱ, R^{j}, and R^{k} have the same meaning as in Formula I.

34. The lithographic printing plate precursor according to claim 22, wherein A is selected from —NR^{h}(SO₂Rⁱ) and —NR^{j}(CO₂R^{k}), wherein R^{h}, Rⁱ, R^{j}, and R^{k} have the same meaning as in Formula III.

35. The lithographic printing plate precursor according to claim 24, wherein A is selected from —NR^{h}(SO₂Rⁱ) and —NR^{j}(CO₂R^{k}), wherein R^{h}, Rⁱ, R^{j}, and R^{k} have the same meaning as in Formula V.

36. The lithographic printing plate precursor according to claim 26, wherein A is selected from —NR^{h}(SO₂Rⁱ) and —NR^{j}(CO₂R^{k}), wherein R^{h}, Rⁱ, R^{j}, and R^{k} have the same meaning as in Formula VII.

37. The lithographic printing plate precursor according to claim 27, wherein A is selected from —NR^{h}(SO₂Rⁱ) and —NR^{j}(CO₂R^{k}), wherein R^{h}, Rⁱ, R^{j}, and R^{k} have the same meaning as in Formula VIII.

38. The lithographic printing plate precursor according to claim 18, wherein the thermoplastic particles have an average particle diameter, measured by Photon Correlation Spectrometry, between 20 nm and 55 nm.

39. The lithographic printing plate precursor according to claim 18, wherein the thermoplastic particles are prepared by emulsion polymerization in the presence of a surfactant selected from alkyl phosphates and alkyl ether phosphates.

40. The lithographic printing plate precursor according to claim 18, wherein the support includes a grained and anodized aluminum support not including a post anodic treatment.

41. A method of preparing a lithographic printing plate comprising the steps of:
exposing a lithographic printing plate precursor as defined in claim 18; and
developing the exposed lithographic printing plate precursor.

42. A method of preparing a lithographic printing plate according to claim 41, wherein the step of developing the exposed lithographic printing plate precursor includes:
developing the lithographic printing plate precursor in an aqueous solution having a pH of at least 9.
